(19) United States
(12) Patent Application Publication
(10) Pub. No.: US 2025/0241176 A1
(43) Pub. Date: Jul. 24, 2025

(54) DISPLAY DEVICE AND METHOD FOR MANUFACTURING THE SAME

(71) Applicant: Samsung Display Co., Ltd., Yongin-si (KR)

(72) Inventors: HWI KIM, Yongin-si (KR); JUNGSUN PARK, Yongin-si (KR); JI-HEE SON, Yongin-si (KR); SEOULKI LEE, Yongin-si (KR); SEUNGJUN LEE, Yongin-si (KR); AREUM LEE, Yongin-si (KR); YEONHWA LEE, Yongin-si (KR); JOONGU LEE, Yongin-si (KR)

(73) Assignee: Samsung Display Co., Ltd., Yongin-si (KR)

(21) Appl. No.: 19/013,707

(22) Filed: Jan. 8, 2025

(30) Foreign Application Priority Data
Jan. 18, 2024 (KR) 10-2024-0007836

(51) Int. Cl. H10K 59/80; H10K 59/12

(52) U.S. Cl. CPC H10K 59/873; H10K 59/1201; H10K 59/80521

(57) ABSTRACT

A display module includes a base layer in which a module hole is defined, a light emitting element including a pixel electrode disposed on the base layer, a counter electrode, and a functional layer, a protrusion pattern disposed between the base layer and the pixel electrode and that defines a pattern hole, a first insulating layer disposed between the base layer and the protrusion pattern and that defines a first opening overlapping the pattern hole, a second insulating layer disposed between the protrusion pattern and the pixel electrode and that defines a second opening overlapping the pattern hole, and an anti-deposition pattern directly disposed on a bottom surface of the protrusion pattern. The counter electrode is disconnected by the anti-deposition pattern and includes a first portion disposed in the first opening and a second portion disposed in the second opening, exhibiting excellent reliability characteristics.

### CROSS-REFERENCE TO RELATED APPLICATION(S)

This U.S. non-provisional patent application claims priority to and benefits of Korean Patent Application No. 10-2024-0007836 under 35 U.S.C. § 119, filed in the Korean Intellectual Property Office on Jan. 18, 2024, the entire contents of which are incorporated hereby by reference.

### BACKGROUND

### 1. Technical Field

The disclosure relates to a display device and a method for manufacturing the display device, and more specifically, to a display device having improved reliability and a method for manufacturing the display device.

### 2. Description of Related Art

A display device, such as a television, mobile phone, tablet, computer, navigation system, game console, etc., may include a display panel for generating and displaying images. In addition to the display panel, the display device may incorporate various electronic components, including input sensors that detect external inputs and electronic modules, such as cameras, infrared sensors, or a proximity sensors.

Recently, to provide a larger display area, the electronic module of the display device may be disposed beneath the display panel, with the display panel featuring a hole to expose the electronic module. To enhance the reliability of such display devices, it is necessary to implement technology for protecting the layers of the display panel that are exposed around the hole.

### SUMMARY

The disclosure provides a display device that prevents moisture and other contaminants from permeating and transmitting through an electrode, thereby achieving excellent display quality and improved product reliability.

The disclosure also provides a method for manufacturing a display device including a disconnected electrode, which prevents an electrode from acting as a moisture permeation path in a hole area.

An embodiment provides a display device including: an electronic module; and a display module including a hole area overlapping the electronic module, wherein the display module includes: a base layer with a module hole corresponding to the hole area; a light emitting element including a pixel electrode disposed on the base layer, a counter electrode facing the pixel electrode, and a functional layer disposed between the pixel electrode and the counter electrode; a protrusion pattern disposed between the base layer and the pixel electrode, forming a pattern hole spaced apart from the module hole and surrounding the module hole; a first insulating layer disposed between the base layer and the protrusion pattern, with a first opening overlapping the pattern hole; a second insulating layer disposed between the protrusion pattern and the pixel electrode, with a second opening overlapping the pattern hole; and an anti-deposition pattern directly disposed on a bottom surface of the protrusion pattern, wherein the counter electrode is disconnected by the anti-deposition pattern and includes a first portion disposed in the first opening and a second portion disposed in the second opening.

In an embodiment, a bottom surface of the anti-deposition pattern may not be covered by the counter electrode in the first opening.

In an embodiment, the anti-deposition pattern may include: a core part comprising at least one substituted or unsubstituted aromatic ring; and an aromatic hydrocarbon compound bonded to the core part, comprising at least one of a fluorine atom and a fluorine substituent.

In an embodiment, the core part may have a molecular weight of less than or equal to about 300 Da and contain 1 to 5 substituted or unsubstituted aryl rings or substituted or unsubstituted heteroaryl rings, and the fluorine substituent may be represented by *—(CF₂)ₙ—CF₃, where n is an integer of greater than or equal to 1 and less than or equal to 9.

In an embodiment, the aromatic hydrocarbon compound may have a molecular weight of greater than or equal to about 500 Da and less than or equal to about 2,000 Da.

In an embodiment, the counter electrode may include an alloy material containing greater than or equal to about 98 vol % of Ag and is free of Mg.

In an embodiment, the pixel electrode may be a reflective electrode, and the counter electrode may be either a transmissive electrode or a transflective electrode.

In an embodiment, the protrusion pattern may not overlap the first insulating layer and the second insulating layer and comprises a protruding tip part, and the anti-deposition pattern may overlap a tip part of the protrusion pattern.

In an embodiment, the anti-deposition pattern may entirely overlap the protrusion pattern.

In an embodiment, the display module may further include an encapsulation layer disposed on the counter electrode, wherein the encapsulation layer may include an encapsulation inorganic layer directly disposed on the counter electrode and the anti-deposition pattern.

In an embodiment, in a cross-section, a width of the first opening in a direction and a width of the second opening in the direction may be each greater than that of the pattern hole in the direction.

In an embodiment, a display device includes: an electronic module; and a display module including a hole area overlapping the electronic module and a display area distinct from the hole area, wherein, in the hole area, the display module includes: a base layer in which a module hole is defined; a circuit layer disposed on the base layer, including a plurality of dam parts that surround the module hole and a groove defined between the dam parts; a display element layer disposed on the circuit layer, including an electrode containing Ag; and an encapsulation layer disposed on the display element layer, wherein the groove includes a pattern hole defined by a protrusion pattern including a tip part protruding inward and an anti-deposition pattern directly disposed below the protrusion pattern; a lower opening defined below the pattern hole, overlapping the pattern hole; and an upper opening overlapping the lower opening in a thickness direction, and the electrode may be disposed on the dam parts and the groove and may expose a bottom surface of the anti-deposition pattern.

In an embodiment, the anti-deposition pattern may include: a core part comprising at least one substituted or unsubstituted aromatic ring; and an aromatic hydrocarbon compound bonded to the core part, comprising at least one of a fluorine atom and a fluorine substituent, wherein the core part may have a molecular weight of less than or equal to about 300 Da and contain 1 to 5 substituted or unsubstituted aryl rings or substituted or unsubstituted heteroaryl rings, and the fluorine substituent may be represented by *—(CF₂)ₙ—CF₃, where n is an integer of greater than or equal to 1 and less than or equal to 9.

In an embodiment, the groove may be provided in plurality, and the encapsulation layer may include: a first encapsulation layer that covers the plurality of grooves; a second encapsulation layer disposed on the first encapsulation layer, overlapping some of the plurality of grooves and not overlapping other grooves; and a third encapsulation layer disposed on the second encapsulation layer to cover the plurality of grooves.

In an embodiment, the first encapsulation layer may be directly disposed on a bottom surface of the anti-deposition pattern, covering the dam parts and the grooves.

In an embodiment, each of the dam parts may include a first dam layer that defines the lower opening and a second dam layer that defines the upper opening and is disposed on the first dam layer, and the protrusion pattern may be disposed between the first dam layer and the second dam layer.

In an embodiment, a method for manufacturing a display device includes: providing a target substrate that comprises a base layer and a preliminary first insulating layer disposed on the base layer; forming an anti-deposition pattern on the target substrate using an aromatic hydrocarbon compound containing at least one of a fluorine atom and a fluorine substituent; forming a protrusion pattern by overlapping the anti-deposition pattern; providing a preliminary second insulating layer on the protrusion pattern; patterning the preliminary first insulating layer and the preliminary second insulating layer to form a first insulating layer, in which a first opening is defined, and a second insulating layer, in which a second opening is defined, and forming a counter electrode that is disposed in the first opening and the second opening, and is disconnected by the anti-deposition pattern.

In an embodiment, in the forming of the counter electrode, the counter electrode may not be disposed on a bottom surface of the protrusion pattern exposed to the first opening.

In an embodiment, the forming of the counter electrode may include providing an alloy containing greater than or equal to about 98 vol % of Ag using a sputtering method.

In an embodiment, the forming of the anti-deposition pattern may include applying the aromatic hydrocarbon compound on the target substrate using a vacuum thermal evaporation method.

### BRIEF DESCRIPTION OF THE FIGURES

The above and other aspects, features, and advantages of embodiments of the disclosure will be more apparent from the following description taken in conjunction with the accompanying drawings, in which:

FIG. 1 is a schematic perspective view of a display device according to an embodiment of the disclosure;

FIG. 2 is a schematic exploded perspective view of a display device according to an embodiment of the disclosure;

FIG. 3 is a schematic cross-sectional view of a display module according to an embodiment of the disclosure;

FIG. 4 is a schematic plan view illustrating a portion of the display module according to an embodiment of the disclosure;

FIG. 5 is a schematic cross-sectional view illustrating a portion of the display module according to an embodiment of the disclosure;

FIG. 6 is a schematic cross-sectional view illustrating a portion of the display module according to an embodiment of the disclosure;

FIG. 7 is a schematic cross-sectional view of an area YY′ of FIG. 6;

FIG. 8 is a schematic cross-sectional view illustrating a portion of the display module according to an embodiment of the disclosure;

FIG. 9 is a schematic cross-sectional view of an area YY′-1 of FIG. 8;

FIG. 10A is a schematic view illustrating a movement path of moisture or gas in a display module according to the related art;

FIG. 10B is a schematic view illustrating a movement path of moisture or gas in a display module according to an embodiment of the disclosure;

FIG. 11 is a schematic flowchart illustrating a method for manufacturing a display device according to an embodiment of the disclosure; and

FIGS. 12A to 12H are schematic views illustrating one process in the method for manufacturing the display device according to an embodiment of the disclosure.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art. Various embodiments do not have to be exclusive nor limit the disclosure. For example, specific shapes, configurations, and characteristics of an embodiment may be used or implemented in another embodiment.

In the drawings, sizes, thicknesses, ratios, and dimensions of the elements may be exaggerated for ease of description and for clarity. Like reference numbers and/or reference characters refer to like elements throughout.

The phrase “in a plan view” means viewing the object from the top, and the phrase “in a schematic cross-sectional view” means viewing a cross-section of which the object is vertically cut from the side. Hence, the expression “in a plan view” used herein may cross-sectional view” means viewing a cross-section in the first x direction or the second y direction of which the object is vertically cut from the side. The third z direction also can be referred to as a “thickness direction.”

It will be understood that when an element (or a layer, a region, a portion, or the like) is referred to as “formed on,” “being on,” “disposed on,” “connected to,” or “coupled to” another element in the specification, it can be directly formed on, disposed on, connected or coupled to another element mentioned above, or intervening elements may be disposed therebetween. It will be understood that the terms “connected to” or “coupled to” may include a physical or electrical connection or coupling.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

In the specification and the claims, the phrase “at least one of” is intended to include the meaning of “at least one selected from the group of” for the purpose of its meaning and interpretation. For example, “at least one of A and B” may be understood to mean “A, B, or A and B.”

It will be understood that, although the terms “first,” “second,” etc. may be used herein to describe various elements, these elements should not be limited by these terms. These terms are only used to distinguish one element from another. For example, a first element may be referred to as a second element, and similarly, a second element may be referred to as a first element without departing from the scope of the disclosure.

As used herein, the singular forms “a,” “an,” and “the” are intended to include the plural forms as well, unless the context clearly indicates otherwise.

The spatially relative terms “below,” “beneath,” “lower,” “above,” “upper,” or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

The terms “comprises,” “comprising,” “includes,” and/or “including,”, “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

In the disclosure, when an element is “directly on,” “directly connected to,” or “directly coupled to” another element, there are no intervening elements present. For example, “directly on” may mean that two layers or two elements are disposed without an additional element such as an adhesion element therebetween.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value.

Embodiments may be described and illustrated in the accompanying drawings in terms of functional blocks, units, and/or modules.

Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies.

In the case of the blocks, units, and/or modules being implemented by microprocessors or other similar hardware, they may be programmed and controlled using software (for example, microcode) to perform various functions discussed herein and may optionally be driven by firmware and/or software.

It is also contemplated that each block, unit, and/or module may be implemented by dedicated hardware, or as a combination of dedicated hardware to perform some functions and a processor (for example, one or more programmed microprocessors and associated circuitry) to perform other functions.

Each block, unit, and/or module of embodiments may be physically separated into two or more interacting and discrete blocks, units, and/or modules without departing from the scope of the disclosure.

Further, the blocks, units, and/or modules of embodiments may be physically combined into more complex blocks, units, and/or modules without departing from the scope of the disclosure.

Unless otherwise defined or implied herein, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, a display device and a method for manufacturing the display device according to an embodiment of the disclosure will be described with reference to the accompanying drawings.

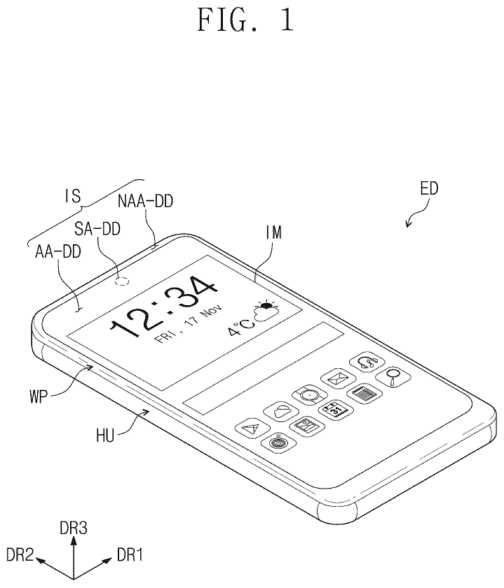

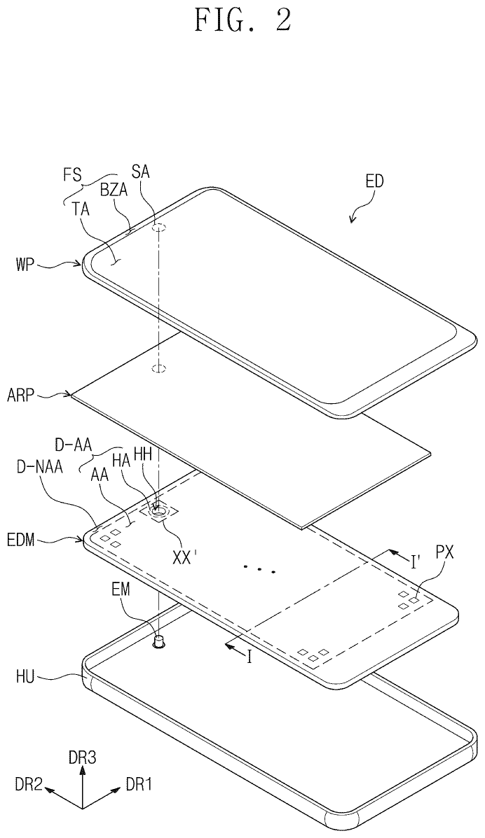

FIG. 1 is a schematic perspective view of a display device according to an embodiment of the disclosure. FIG. 2 is a schematic exploded perspective view of the display device according to an embodiment of the disclosure.

A display device ED may be a device that operates according to an electrical signal to display an image. The display device ED may include various embodiments that provide an image to a user. For example, the display device ED may include large-sized devices such as televisions, external billboards, and the like, as well as small and medium-sized devices such as monitors, mobile phones, computers, tablets, navigation systems, game consoles, and the like. The embodiments of the display device ED are merely examples and are not limited thereto unless departing from the concept of the disclosure. In this specification, a mobile phone is illustrated as an example of the display device ED.

Referring to FIG. 1, the display device ED may have a rectangular shape that has short sides extending in a first direction DR1 and long sides extending in a second direction DR2. However the disclosure is not limited thereto, and the display device ED may have various shapes such as a circular shape or a polygonal shape.

The display device ED may display an image IM in the third direction DR3 on a display surface IS parallel to a surface defined in the first and second directions DR1 and DR2. The third direction DR3 may be substantially parallel to a normal direction of the display surface IS. A display surface IS of the display device ED may correspond to a front surface of the display device ED.

An image IM displayed on the display device ED may include both still images and dynamic images. FIG. 1 illustrates a watch window and a plurality of icons as an example of the image IM.

In an embodiment, a front surface (or a top surface) or a rear surface (or a bottom surface) of each of members or units may be defined based on a direction in which the image IM is displayed. The front and rear surfaces may be opposite each other in the third direction DR3. A normal direction of each of the front and rear surfaces may be substantially parallel to the third direction DR3. A spaced distance between the front surface and the rear surface defined along the third direction DR3 may correspond to a thickness of the member (or unit).

In this specification, the term “in a plan view” may refer to a state when viewed in the third direction DR3. The term “on the cross-section” may refer to a state when viewed from the first direction DR1 or the second direction DR2. The directions indicated as the first, second, and third directions DR1, DR2, and DR3 may be a relative concept and may vary depending on the orientation.

The display device ED may be flexible. The “flexible” refers to a bendable property and may include a structure that is completely folded down to a few nanometers. For example, the flexible display device ED may include a curved device or a foldable device. However, an embodiment of the disclosure is not limited to flexible devices, and the display device ED may also be a rigid display device.

FIG. 1 schematically illustrates an example of the display device ED having a planar display surface IS. However, a shape of the display surface IS of the display device ED is not limited to a planar form and may be curved or have a three-dimensional shape.

The display surface IS of the display device ED may include a display part AA-DD and a non-display part NAA-DD. The display part AA-DD may be a portion where the image IM is displayed on the front surface of the display device ED, allowing a user to visually recognize the image IM through the display part AA-DD. Although this embodiment illustrates the display part AA-DD as having a square shape, the display part AA-DD may have various shapes depending on a design of the display device ED.

The non-display part NAA-DD may be a portion where the image IM is not displayed on the front surface of the display device ED. The non-display part NAA-DD may have a selected color and may be a portion that blocks light. The non-display part NAA-DD may be adjacent to the display part AA-DD. For example, the non-display part NAA-DD may be disposed outside the display part AA-DD to surround the display part AA-DD. However, this is merely an example, and the non-display part NAA-DD may be adjacent to only one side of the display part AA-DD or may also be disposed on a side surface of the display device ED instead of the front surface. An embodiment of the disclosure is not limited thereto. In an embodiment, the non-display part NAA-DD may be omitted.

The display part AA-DD of the display device ED according to an embodiment may include a sensing area SA-DD. The sensing area SA-DD may correspond to an area where an electronic module EM of FIG. 2 overlaps. The electronic module EM may receive an external input through the sensing area SA-DD or provide an output through the sensing area SA-DD. FIG. 1 illustrates one example of sensing area SA-DD disposed in the display part AA-DD, but is not limited thereto. For example, multiple sensing area SA-DD may also be provided in the display part AA-DD.

The display device ED according to an embodiment may sense various forms of external input, such as a pressure, a temperature, and light provided from the outside. The external input may include direct contact with the display device ED (e.g., from a user's hand or a pen) as well as proximity-based inputs to the display device ED (e.g., hovering near the display device ED).

Referring to FIGS. 1 and 2, the display device ED may include a window WP and a housing HU. The window WP and the housing HU may be coupled together to form an outer appearance of the display device ED and provide an internal space that accommodates components of the display device ED. Components such as a display module EDM, a light control member ARP, and an electronic module EM may be disposed between the window WP and the housing HU.

The electronic module EM may be disposed beneath the display module EDM and may overlap the display module EDM. The electronic module EM may be an electronic component that outputs or receives optical signals. For example, the electronic module EM could be a camera module for capturing external images. However, this is not limiting, as the electronic module EM may also be a sensor module such as a proximity sensor or an infrared light emitting sensor.

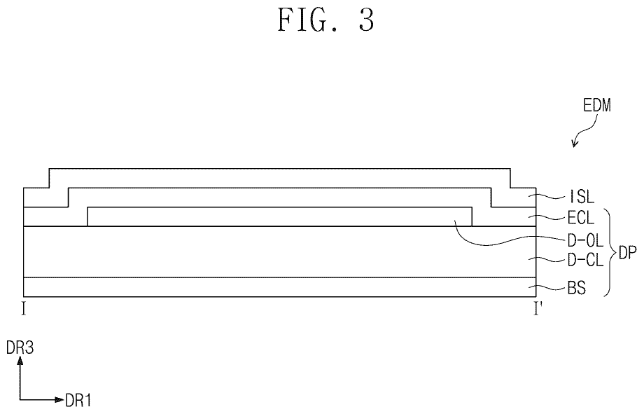

The display module EDM may be disposed above the electronic module EM. The display module EDM may include a display panel DP (see FIG. 3), which will be described later. The display panel DP may generate an image based on an electrical signal. The display panel DP (FIG. 3) could be an emissive display panel, but is not limited to this type.

The display module EDM may include an active region D-AA and a peripheral region D-NAA adjacent to the active region D-AA. The active region D-AA may be an area activated by an electrical signal. A plurality of pixels PX may be disposed in the active region D-AA.

The peripheral region D-NAA may surround the active region D-AA. The peripheral region D-NAA may include a driving circuit or driving line for operating the pixels PX in the active region D-AA, along with various signal lines or pads that provide electrical signals to other components.

The display module EDM may include a hole area HA disposed in the active region D-AA. The hole area HA may correspond to the sensing area SA-DD of the display device ED. In this specification, in the case where it is stated that “one area/portion corresponds to another area/portion,” it means that they overlap, but they do not necessarily have the same area and/or the same shape. The hole area HA may also be referred to as a first area HA.

The hole area HA may be an area overlapping the electronic module EM. A module hole HH may be defined in the hole area HA. In an embodiment, the module hole HH may be a through-hole passing (or extending) through the display module EDM, overlapping the electronic module EM. In an embodiment, a portion of the electronic module EM may be inserted into the module hole HH.

FIG. 2 schematically illustrates one module hole HH having a circular shape as an example, but it is not limited to this configuration. The number of module holes HH may correspond to the number of electronic modules EM disposed below the display module EDM. The shape of the module hole HH in a plan view may be polygonal, or oval, or other forms depending on the shape or arrangement of the electronic module EM.

The display device ED may receive an external signal required for the electronic module EM or transmit a signal output from the electronic module EM through the sensing area SA-DD. According to an embodiment of the disclosure, the hole area HA may be provided in the active region D-AA, thereby reducing a surface area of the non-display part NAA-DD used for positioning the electronic module EM.

At least a portion of the hole area HA may be surrounded by the display area AA, which may also be referred to as a second area. The active region D-AA of the display module EDM according to an embodiment may include both a hole area HA and a display area AA. In an embodiment, the hole area HA may be entirely surrounded by the display area AA, but it is not limited to this arrangement, as a portion of the hole area HA may be surrounded by the display area AA with a remaining portion in contact with the peripheral region D-NAA.

The display device ED may include a light control member ARP disposed between the display module EDM and the window WP. The light control member ARP may be a reflection reduction layer that reduces external light reflectance caused by light incident from outside the display device ED. However, this embodiment is not limited thereto, and the light control member ARP may include various light control layers to enhance display quality of the display device ED. For example, the light control member ARP according to an embodiment may include a polarizing layer, a phase retarder, a destructive interference structure, or multiple color filters. In an embodiment, the light control member ARP may be omitted in the display device ED.

A portion of the light control member ARP overlapping the hole area HA may have relatively high light transmittance. For example, the light control member ARP may include a transmission part overlapping the hole area HA, but is not limited thereto, and the light control member ARP may also include a hole overlapping the hole area HA to allow light to pass through the light control member ARP.

The window WP may be disposed on the light control member ARP. The window WP may protect the display module EDM and the light control member ARP disposed below the window WP.

The window WP may include an optically transparent insulating material. For example, the window WP may include glass, sapphire, or plastic. The window WP may have a single-layer or multi-layer structure. The window WP may further include a functional layer such as an anti-fingerprint layer, a phase control layer, and a hard coating layer on an optically transparent substrate.

A front surface FS of the window WP may correspond to the display surface IS of the display device ED described above. The front surface FS of the window WP may include a transmission area TA and a bezel area BZA.

The transmission area TA of the window WP may be an optically transparent area. The transmission area TA may correspond to the display part AA-DD of display device ED. The transmission area TA may overlap at least a portion of the active region D-AA of the display module EDM, allowing the window WP to transmit an image provided by the display module EDM through the transmission area TA for visual recognition by the user.

The transmission area TA of the window WP may include a sensing area SA. The sensing area SA of the window WP may correspond to the sensing area SA-DD of the display device ED. The sensing area SA of the window WP may overlap the hole area HA and the electronic module EM. The sensing area SA of the window WP may have relatively high light transmittance, enabling the electronic module EM to effectively receive an external input or transmit a signal through the sensing area SA.

The bezel area BZA of the window WP may be formed by depositing, coating, or printing a material having a selected color on a transparent substrate. The bezel area BZA may correspond to the non-display part NAA-DD of the display device ED. The bezel area BZA may overlap at least a portion of the peripheral region D-NAA of the display module EDM. The bezel area BZA of the window WP may cover the peripheral region D-NAA of the display module EDM, thereby concealing a configuration of the display module EDM in the peripheral region D-NAA from external view.

The housing HU may be disposed below the display module EDM. The housing HU may protect components accommodated in the housing HU. The housing HU may prevent an infiltration of foreign substances or moisture into the display module EDM and the light control member ARP from the outside. The housing HU may include a material with relatively high rigidity, and the housing HU may absorb an external impact from the outside. In an embodiment, the housing HU may include a structure where multiple accommodation members are coupled together.

FIG. 3 is a schematic cross-sectional view of the display module according to an embodiment of the disclosure, taken along line I-I′ of FIG. 2.

Referring to FIG. 3, the display module EDM according an embodiment may include a display panel DP and an input sensor ISL. The display panel DP may include a base layer BS, a circuit layer D-CL, a display element layer D-OL, and an encapsulation layer ECL.

The base layer BS may be a member that provides a base surface on which the circuit layer D-CL is disposed. The base layer BS may be a rigid substrate or a flexible substrate, capable of being bent, folded, or rolled. The base layer BS may include materials such as glass, metal, silicon, or polymer. However, the embodiment is not limited to these materials. For example, the base layer BS may also be an inorganic layer, an organic layer, or a composite layer.

The base layer BS may have a multi-layer structure. For example, the base layer BS may include a first polymer resin layer, a silicon oxide (SiOₓ) layer disposed on the first polymer resin layer, an amorphous silicon (a-Si) layer disposed on the silicon oxide layer, and a second polymer resin layer disposed on the amorphous silicon layer. The silicon oxide layer and the amorphous silicon layer may collectively be referred to as a base barrier layer.

Each of the first and second polymer resin layers may include a polyimide-based resin. The polymer resin layers may include at least one of an acrylate-based resin, a methacrylate-based resin, a polyisoprene-based resin, a vinyl-based resin, an epoxy-based resin, an urethane-based resin, a cellulose-based resin, a siloxane-based resin, a polyamide-based resin, or a perylene-based resin. In this specification, the term “˜˜-based” resin refers to a resin that includes a functional group of “˜˜”.

The circuit layer D-CL may be disposed on the base layer BS. The circuit layer D-CL may include an insulating layer, a semiconductor pattern, a conductive pattern, and a signal transfer area. The insulating layer, the semiconductor layer, and the conductive layer may be formed on the base layer BS through methods such as coating or vapor deposition, followed by selective patterning through multiple photolithography processes. Thus, the circuit layer D-CL may be formed to include the semiconductor pattern, the conductive pattern, and the signal line.

The display element layer D-OL may be disposed on the circuit layer D-CL. The display element layer D-OL may include a light emitting element. For example, the display element layer D-OL may include an organic light emitting material, an inorganic light emitting material, an organic-inorganic light emitting material, a quantum dot, a quantum rod, a micro LED, or a nano LED.

The encapsulation layer ECL may be disposed on the display element layer D-OL. The encapsulation layer ECL may protect the display element layer D-OL from foreign substances such as moisture, oxygen, and dust particles. The encapsulation layer ECL may be disposed directly on the display element layer D-OL or may be combined with the display element layer D-OL through a separate member.

In the display module EDM according to an embodiment, the input sensor ISL may be disposed on the encapsulation layer ECL. The input sensor ISL may be disposed on the encapsulation layer ECL through a continuous process. The input sensor ISL may be described as being disposed (e.g., directly disposed) on the encapsulation layer ECL, meaning no third component is disposed between the input sensor ISL and the encapsulation layer ECL. For example, a separate adhesive member may not be disposed between the input sensor ISL and the encapsulation layer ECL. In another embodiment, the input sensor ISL and the encapsulation layer ECL may be coupled together using an adhesive member. The adhesive member may include a common adhesive or an adhesive agent.

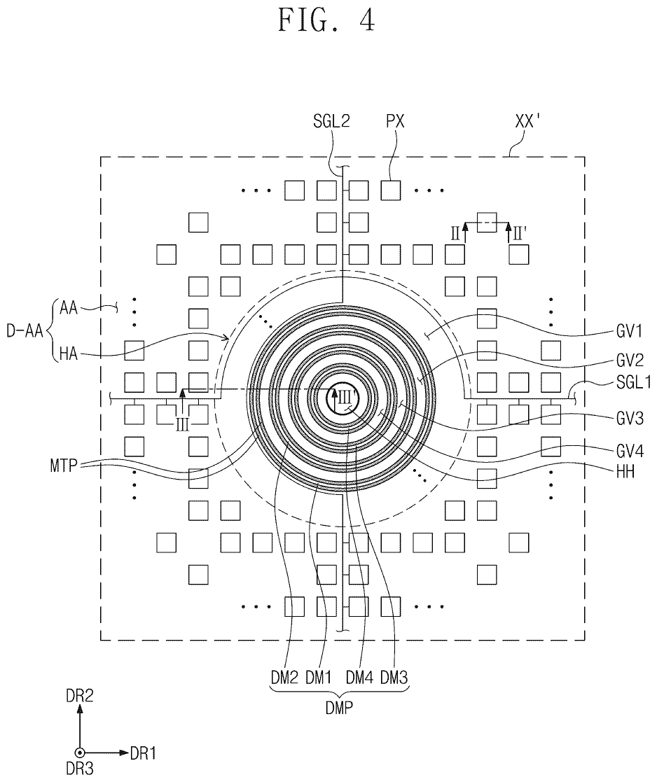

FIG. 4 is a schematic plan view illustrating a portion of the display module according to an embodiment of the disclosure. FIG. 4 illustrates an area XX′ of FIG. 2, which corresponds to a portion of the active region D-AA, including the module hole HH.

Referring to FIG. 4, a plurality of pixels PX may be disposed on the active region D-AA of the display module EDM. In an embodiment, most of the pixels PX of the plurality of pixels PX may be disposed on the display area AA (or second area) spaced apart from the hole area HA, and some of the pixels PX may be disposed on the display area AA along a boundary between the hole area HA (or first area) and the display area AA. The pixels PX adjacent to the boundary of the hole area HA may be disposed to be spaced apart from the module hole HH.

The module hole HH may be defined in the hole area HA. The module hole HH may be defined in the active region D-AA. Thus, at least some of the pixels PX may be disposed adjacent to the module hole HH, and the pixels PX may be disposed to be spaced apart from each other with the module hole HH between them. The electronic module EM may overlap the module hole HH.

A dam pattern DMP may be disposed in the hole area HA. According to an embodiment, the display device ED (see FIG. 2) may block a path through which moisture and/or oxygen could be introduced from the module hole HH to the pixels PX by the dam pattern DMP. The dam pattern DMP may be disposed in the hole area HA and include at least one dam part DM1, DM2, DM3, and DM4. Each of the dam parts DM1, DM2, DM3, and DM4 may surround at least a portion of the module hole HH. According to an embodiment, each of the dam parts DM1, DM2, DM3, and DM4 may have a closed-line shape surrounding the module hole HH in a plan view.

In an embodiment, at least one protrusion pattern MTP may be disposed in the hole area HA. The protrusion pattern MTP may surround at least a portion of the module hole HH. In a plan view, the protrusion pattern MTP of the display device according to an embodiment may have a closed-line shape surrounding the module hole HH. However, this embodiment of the disclosure is not limited to this configuration.

At least a portion of the protrusion pattern MTP may overlap the dam pattern DMP. In an embodiment, the protrusion pattern MTP may be disposed to overlap each of the dam parts DM1, DM2, DM3, and DM4. The protrusion pattern MTP may overlap at least a portion of the dam parts DM1, DM2, DM3, and DM4 and may protrude in a direction toward or away from the module hole HH in a plan view.

At least one groove GV1, GV2, GV3, and GV4 may be defined in the hole area HA. The grooves GV1, GV2, GV3, and GV4 may be defined as surrounding the module hole HH. The grooves GV1, GV2, GV3, and GV4 may be defined between the dam parts DM1, DM2, DM3, and DM4 or between the dam part DM1 and the display area AA. In an embodiment, the grooves GV1, GV2, GV3, and GV4 may be defined by the dam parts DM1, DM2, DM3, and DM4 or the protrusion pattern MTP.

In an embodiment, a filling material may be further disposed inside the module hole HH. The filling material may include a polymer resin, providing a flat surface for components disposed on the module hole HH. A material that is transparent and does not have optical anisotropy may be used as the filling material. The filling material may be used without limitation as long as it does not impair sensing ability of the electronic module EM (see FIG. 2). The filling material may also be omitted.

A portion of each of the plurality of signal lines SGL1 and SGL2 connected to the pixels PX may be disposed in the hole area HA. The signal lines SGL1 and SGL2 may connect to the pixels PX spaced apart from each other with the module hole HH between them via the hole area HA. For illustrative purposes, FIG. 4 shows two signal lines SGL1 and SGL2 among the plurality of signal lines connected to the pixels PX.

The first signal line SGL1 may extend in the first direction DR1. The first signal line SGL1 may connect the pixels in the same row arranged in the first direction DR1 of the pixels PX. The first signal line SGL1 may correspond to any one of scan lines connected to the pixels PX.

Some of the pixels PX connected to the first signal line SGL1 may be disposed on the left side of the module hole HH, while others may be disposed on the right side of the module hole HH. Thus, the pixels in the same row connected to the first signal line SGL1 may be turned on or off by substantially the same gate signal, even though some of the pixels PX with respect to the module hole HH are omitted.

The second signal line SGL2 may extend in the second direction DR2. The second signal line SGL2 may connect the pixels PX arranged in the same column in the second direction DR2. The second signal line SGL2 may correspond to any one of the data lines connected to the pixels PX.

Some of the pixels PX connected to the second signal line SGL2 may be disposed above the module hole HH, while others may be disposed below the module hole HH. Thus, the pixels in the same column connected to the second signal line SGL2 may receive a data signal through the same line, even though some of the pixels PX with respect to the module hole HH are omitted.

At least one of the first signal line SGL1 or the second signal line SGL2 may be disconnected in the hole area HA at a crossing point (e.g., at which the first signal line SGL1 and the second signal line SGL2 cross each other), and a connection pattern disposed on a different layer from the disconnected signal line may reconnect the separated portions. However, the connection relationship between the pixels PX spaced apart with the module hole HH between them is not limited to this configuration.

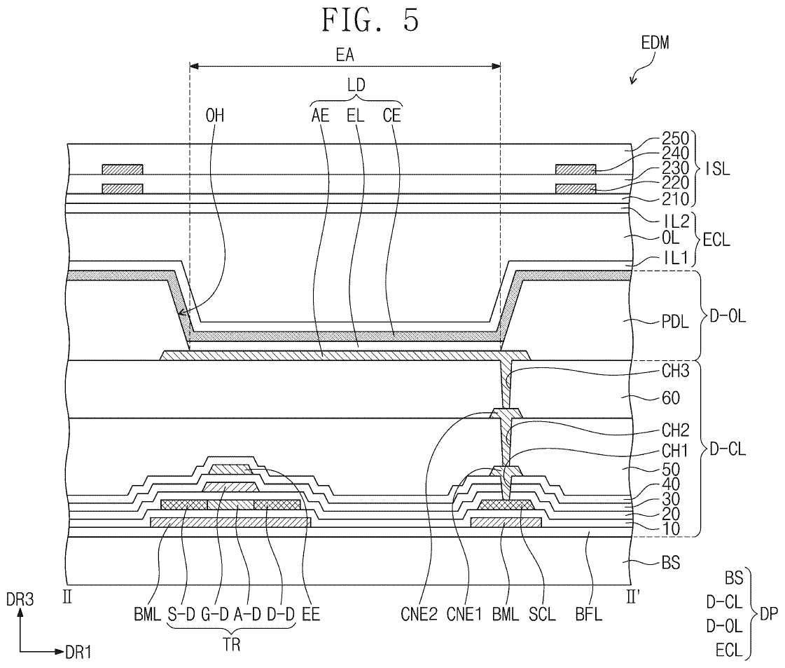

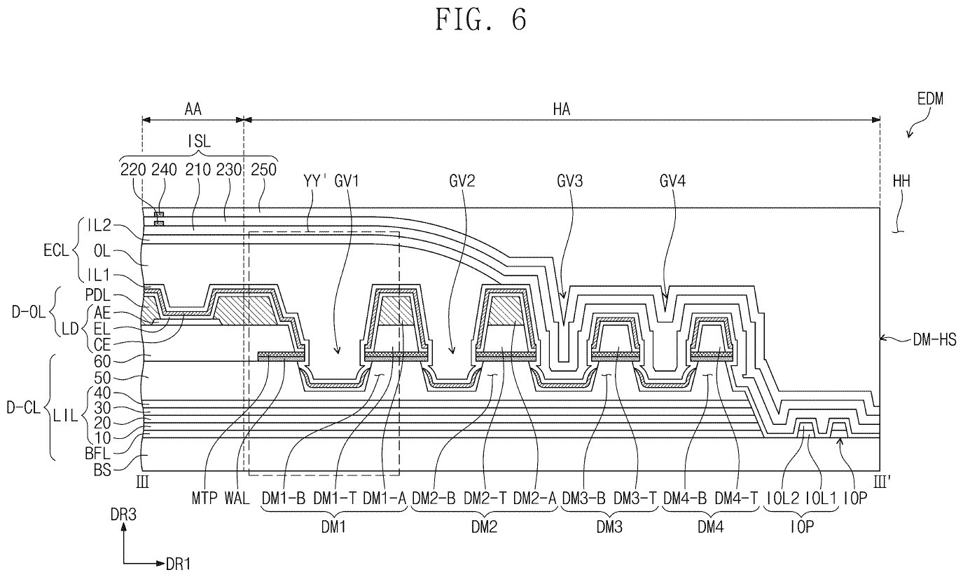

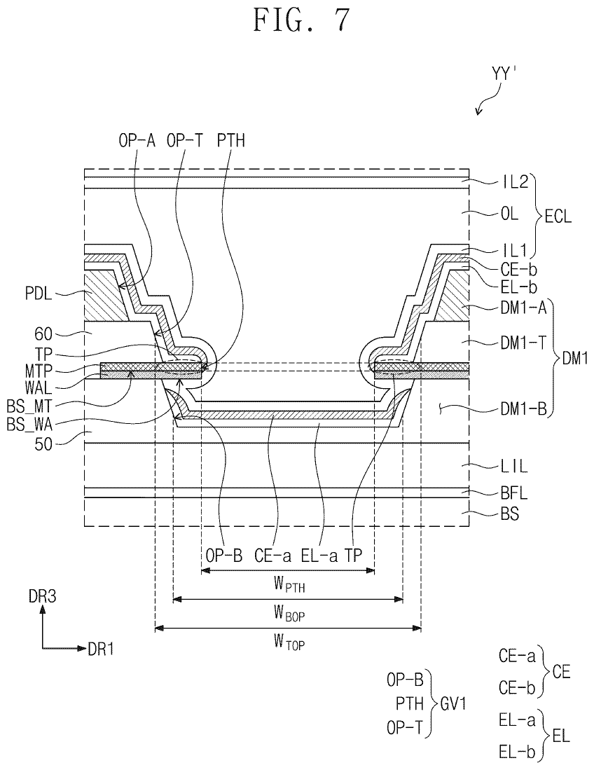

FIGS. 5 and 6 are schematic cross-sectional views illustrating a portion of the display module according to an embodiment. FIG. 7 is a schematic enlarged view illustrating a portion of the display module according to an embodiment. FIG. 5 illustrates a portion corresponding to line II-II′ of FIG. 4. FIG. 6 is a portion corresponding to line III-III′ of FIG. 4, and FIG. 7 is a schematic enlarged view of area YY′ of FIG. 6. FIG. 5 illustrates a portion of the display area AA (see FIG. 4), and FIGS. 6 and 7 illustrate a portion of the hole area HA (see FIG. 4).

FIG. 5 illustrates a portion corresponding to the pixel PX (see FIG. 4) as an example. In FIG. 5, one transistor TR and a light emitting element LD included in the pixel PX (see FIG. 4) are illustrated as an example.

Referring to FIGS. 5 and 6, the display module EDM may include a display panel DP and an input sensor ISL. The display panel DP may include a base layer BS, a circuit layer D-CL, a display element layer D-OL, and an encapsulation layer ECL, which are sequentially stacked. The display module EDM according to an embodiment may also include a protrusion pattern MTP and an anti-deposition pattern WAL.

The circuit layer D-CL may include a buffer layer BFL, a shielding electrode BML, a transistor TR, a signal transfer area SCL, multiple insulating layers 10, 20, 30, 40, 50, and 60, and connection electrodes CNE1 and CNE2.

Although not shown, the circuit layer D-CL may further include various conductive patterns, such as additional transistors, capacitors, or other conductive elements constituting connection electrodes beyond the transistor TR. The configuration of the circuit layer D-CL illustrated in FIG. 5 is illustrative, and the types, numbers, and arrangements of conductive patterns and insulating layers may vary.

In an embodiment, the protrusion pattern MTP and the anti-deposition pattern WAL may be disposed in the hole area HA. In an embodiment, the protrusion pattern MTP may be disposed on the same layer as one of the conductive patterns of the circuit layer D-CL, one of the insulating layers 10, 20, 30, 40, 50, and 60, or one of the connection electrodes CNE1 and CNE2. In an embodiment, the protrusion pattern MTP may also be formed in the same process as one of the conductive patterns of the circuit layer D-CL, one of the insulating layers 10, 20, 30, 40, 50, and 60, or one of the connection electrodes CNE1 and CNE2. In an embodiment, in the case where the base layer BS has a multi-layer structure, the protrusion pattern MTP may be disposed between stacked polymer resin layers. For example, the protrusion pattern MTP may be disposed on the same layer as the base barrier layer or may be formed during the same process as the base barrier layer.

The anti-deposition pattern WAL may be disposed below the protrusion pattern MTP. In the case where the protrusion pattern MTP is formed during the same process as the base barrier layer, the anti-deposition pattern WAL may be included in the base layer BS. In the case where the protrusion pattern MTP is formed during the same process as one of the conductive patterns of the circuit layer D-CL, one of the insulating layers 10, 20, 30, 40, 50, and 60, or one of the connection electrodes CNE1 and CNE2, the anti-deposition pattern WAL may be included in the circuit layer D-CL.

In an embodiment, the module hole HH may be defined in the base layer BS. The module hole HH may be defined by passing through the base layer BS in the hole area HA. Each of the protrusion pattern MTP and the anti-deposition pattern WAL may be disposed to surround the module hole HH.

The buffer layer BFL may be disposed on the base layer BS. The buffer layer BFL may improve bonding force between the base layer BS and the semiconductor pattern or the conductive pattern deposited on the buffer layer BFL. The buffer layer BFL may prevent the diffusion of metal atoms or impurities from the base layer BS into the semiconductor pattern or the conductive pattern.

The buffer layer BFL may be an inorganic layer. The buffer layer BFL may include at least one of silicon oxide, silicon nitride, or silicon oxynitride. For example, the buffer layer BFL may have a laminated structure of alternating silicon oxide and silicon nitride layers. In an embodiment, the buffer layer BFL may be omitted.

The shielding electrode BML may be disposed on the buffer layer BFL. The shielding electrode BML may overlap the transistor TR. In an embodiment, the shielding electrode BML may also be disposed below the signal transfer area SCL. The shielding electrode BML may block light incident from a lower side of the display panel DP from entering the transistor TR or the signal transfer area SCL, thereby protecting the semiconductor pattern or the conductive pattern, such as the transistor TR and the signal transfer area SCL. The shielding electrode BML may include a conductive material. In the case where the voltage is applied to the shielding electrode BML, the shielding electrode BML may maintain a threshold voltage of the transistor TR. Without being limited thereto, the shielding electrode BML may be a floating electrode. In an embodiment, the shielding electrode BML may be omitted.

The circuit layer D-CL may include sequentially stacked insulating layers 10, 20, 30, 40, 50, and 60. The insulating layers 10, 20, 30, 40, 50, and 60 may be disposed on the buffer layer BFL. Each of the insulating layers 10, 20, 30, 40, 50, and 60 may be an inorganic or organic layer. For example, in an embodiment, each of the first to fourth lower insulating layers 10, 20, 30, and 40 may include an inorganic layer, and each of the first insulating layer 50 and the second insulating layer 60 may include an organic layer. However, the embodiment of the disclosure is not limited to these configurations. The circuit layer D-CL may include the insulating layers 10, 20, 30, 40, 50, and 60, from which at least one is omitted, or may further include an additional insulating layer.

A first lower insulating layer 10 may be disposed on the buffer layer BFL. The first lower insulating layer 10 may include inorganic material, such as aluminum oxide, titanium oxide, silicon oxide, silicon nitride, silicon oxynitride, zirconium oxide, hafnium oxide, or a combination thereof. The first lower insulating layer may be referred to as a first inorganic layer. The first lower insulating layer 10 may have a single layer or multi-layer structure. The first lower insulating layer 10 may have a structure that includes multiple laminated inorganic layers.

In an embodiment, the first insulating layer may also include an organic layer along with the inorganic layer. In the case where the first lower insulating layer 10 includes laminated inorganic and organic layers, a buffer inorganic layer may be disposed between the inorganic layer and the organic layer.

The description for the first lower insulating layer 10 may apply to the second to fourth lower insulating layers 20, 30, and 40. The second to fourth lower insulating layers 20, 30, and 40 may be referred to as second to fourth inorganic layers, respectively. Each of the second to fourth lower insulating layers 20, 30, and 40 may have a single layer or multi-layer structure. For example, each of the second to fourth lower insulating layers 20, 30, and 40 may independently include at least one of silicon oxide, silicon nitride, or silicon oxynitride.

A semiconductor pattern may be disposed on the circuit layer D-CL. The semiconductor pattern may include polysilicon. However, the embodiment of the disclosure is not limited thereto. For example, the semiconductor pattern may include amorphous silicon or metal oxide, with varying electrical properties depending on doping. The semiconductor pattern may include a first region having a high doping concentration and a second region having a low doping concentration. The first region may be doped with either an N-type dopant or a P-type dopant. A P-type transistor may include the first region doped with the P-type dopant.

The first region may have greater conductivity than the second region and may substantially function as an electrode or a signal line. The second region may substantially correspond to an active (or channel) of the transistor. Thus, a portion of the semiconductor pattern may function as an active region of the transistor, another portion may function as a drain of the transistor, and yet another portion may form a conductive area.

Referring to FIG. 5, in an embodiment, a transistor TR may be disposed on the first lower insulating layer 10. Although not shown, the transistor TR may be electrically connected to the light emitting element LD. The transistor TR may include a source S-D, an active A-D, and a drain D-D formed from the semiconductor pattern. FIG. 5 illustrates a portion of a signal transmission area SCL formed from the semiconductor pattern. The signal transfer area SCL may be disposed on the first lower insulating layer 10. Although not explicitly shown, the signal transmission area SCL may contact the drain D-D of the transistor TR in a plan view.

The second lower insulating layer 20 may cover the source S-D, the active A-D, the drain D-D, and the signal transmission area SCL of the transistor TR disposed on the first lower insulating layer 10. The gate G-D of the transistor TR may be disposed on the second lower insulating layer 20. The third lower insulating layer 30 may be disposed on the second lower insulating layer 20 to cover the gate G-D. An upper electrode pattern EE may be disposed on the third insulating layer 30. The fourth insulating layer 40 may be disposed on the third insulating layer 30 to cover the upper electrode pattern EE.

The first connection electrode CNE1 may be disposed on the fourth insulating layer 40. The first connection electrode CNE1 may connect to the signal transmission area SCL through a contact hole CH1 that passes through the second to fourth insulating layers 20 to 40. The first insulating layer 50 may be disposed on the fourth lower insulating layer 40 to cover the first connection electrode CNE1. The first insulating layer 50 may be an organic layer. The first insulating layer 50 may be referred to as a first organic layer.

The second connection electrode CNE2 may be disposed on the first insulating layer 50. The second connection electrode CNE2 may connect to the first connection electrode CNE1 through a contact hole CH2 that passes through the first insulating layer 50. The second insulating layer 60 may be disposed on the first insulating layer 50 to cover the second connection electrode CNE2. The second insulating layer 60 may be an organic layer. The second insulating layer 60 may be referred to as a second organic layer.

The first insulating layer 50 and the second insulating layer 60 may each include at least one of an acrylate-based resin, a methacrylate-based resin, a polyisoprene-based resin, a vinyl-based resin, an epoxy-based resin, a urethane-based resin, a cellulose-based resin, a siloxane-based resin, a polyamide-based resin, or a perylene-based resin.

The display element layer D-OL may be disposed on the circuit layer D-CL. The display element layer D-OL may include a light emitting element LD and a pixel defining layer PDL. The light emitting element LD may include a first electrode AE, a second electrode CE facing the first electrode AE, and a functional layer EL disposed between the first electrode AE and the second electrode CE.

A light emitting opening OH exposing a portion of a top surface of the first electrode AE may be defined in the pixel defining layer PDL. An emission area EA may correspond to the light emitting opening OH.

The first electrode AE may be disposed on the circuit layer D-CL. In an embodiment, the first electrode AE may be disposed on the second insulating layer 60 of the circuit layer D-CL. The first electrode AE may connect to the second connection electrode CNE2 through a contact hole CH3 that passes through the second insulating layer 60. Thus, the first electrode AE may be electrically connected to the signal transfer area SCL through the first and second connection electrodes CNE1 and CNE2 and then electrically connected to corresponding circuit element. The first electrode AE may include a single layer or multi-layer structure.

The first electrode AE may function as either an anode or a cathode. The first electrode AE may be referred to as a pixel electrode. The second electrode CE may function as a cathode or an anode. The second electrode CE may be referred to as a common electrode. For example, in the case where the first electrode AE is the anode, the second electrode CE may be the cathode, and in the case where the first electrode AE is the cathode, the second electrode CE may be the anode. In an embodiment, the first electrode AE may be referred to as a pixel electrode, and the second electrode CE may be referred to as a counter electrode.

The first electrode AE may be exposed through the light emitting opening OH defined in the pixel defining layer PDL. The first electrode AE may have conductivity. The first electrode AE may include a metal, a metal alloy, or a conductive compound.

In an embodiment, the first electrode AE may be a reflective electrode. The first electrode AE may include at least one selected from Ag, Mg, Cu, Al, Pt, Pd, Au, Ni, Nd, Ir, Cr, Li, Ca, LiF, Mo, Ti, W, In, Sn, and Zn, two or more kinds of compounds selected from the above-described materials, a mixture of two or more kinds of above-described materials, or oxides thereof.

The first electrode AE may include transparent metal oxide such as indium tin oxide (ITO), indium zinc oxide (IZO), zinc oxide (ZnO), or indium tin zinc oxide (ITZO). The first electrode AE may include Ag, Mg, Cu, Al, Pt, Pd, Au, Ni, Nd, Ir, Cr, Li, Ca, LiF/Ca (a laminated structure of LiF and Ca), LiF/Al (a laminated structure of LiF and Al), Mo, Ti, W, or a compound or mixture thereof (for example, a mixture of Ag and Mg). In another embodiment, the first electrode AE may have a multi-layer structure that includes a reflective layer or transflective layer including the above-described material, indium tin oxide (ITO), indium zinc oxide (IZO), zinc oxide (ZnO), or indium tin zinc oxide (ITZO). For example, the first electrode AE may have a three-layer structure of ITO/Ag/ITO, but is not limited to this configuration. For example, the first electrode AE may include the above-described metal material, a combination of two or more metal materials selected from the above-described metal materials, or oxide of the above-described metal materials, but is not limited thereto.

The light emitting element LD may include a second electrode CE facing the first electrode AE. In an embodiment, the second electrode CE may be a transmissive electrode or a transflective electrode. The second electrode CE may contain silver (Ag). The second electrode CE may include Ag as a main metal material and may further include a dopant material. The second electrode CE may include at least one of Al, Au, Cu, Ti, In, Ni, C, Pd, F, Na, Si, Ca, Mn, Fe, Co, Zn, Ga, Ge, Mo, Sn, In, Pt, Pb, Fe, Yb, Lu, or Pa as a dopant material. In an embodiment, the second electrode CE may not contain Mg. For example, the second electrode CE may include an alloy material including Ag, Pd, and Cu. However, the embodiment of the disclosure is not limited thereto.

The content of Ag in the second electrode CE may be greater than or equal to about 98 vol % of the entire second electrode CE. As the second electrode CE may include a metal material having a high content of Ag, it may exhibit low resistance characteristics. A display module EDM including the second electrode CE of a high content of Ag may exhibit low sheet resistance characteristics. In an embodiment, the second electrode CE may exhibit sheet resistance characteristics of less than or equal to about 10Ω/□.

The second electrode CE may be manufactured using a sputtering method, which tends to produce a higher Ag content compared to a thermal evaporation method. This can lead to lower resistance and higher transmittance for the second electrode CE.

The second electrode CE manufactured by the sputtering method may exhibit excellent step coverage characteristics, allowing it to form continuously without disconnection, even on inclined side surfaces and on a lower portion of the pattern having an undercut shape.

Touch noise may be reduced in a display module EDM that includes the second electrode CE made of a high-content Ag material. The low resistance characteristics of the second electrode CE help reduce interference between the display element layer D-OL and the input sensor ISL, thereby minimizing sensing noise in the input sensor ISL. The improved electrical characteristics of the second electrode CE may enhance the light efficiency of the light emitting element LD.

The second electrode CE may be provided as a common layer in common to the plurality of pixels PX (see FIG. 4) or may be shared among the plurality of pixels PX. The second electrode CE may also extend to the hole area HA. In an embodiment, the second electrode CE may be disconnected in a portion of the hole area HA. The second electrode CE may be disconnected at locations where the protrusion pattern MTP is present. The arrangement of the second electrode CE and the protrusion pattern MTP will be described in more detail later.

The light emitting element LD may include a functional layer EL disposed between the first electrode AE and the second electrode CE. The functional layer EL may include at least one emission layer.

The emission layer may include a light emitting material such as an organic material or quantum dots. The functional layer EL, including the emission layer, may emit light in at least one of the colors blue, red, and green colors in a separate pixel. In an embodiment, the functional layer EL may provide blue light throughout the active region D-AA (see FIG. 4), and the display module EDM may further include a color conversion member disposed on the display element layer D-OL.

The functional layer EL may further include a hole control layer and an electron control layer in addition to the emission layer. The hole control layer may be disposed between the first electrode AE and the emission layer, and the electron control layer may be disposed between the emission layer and the second electrode CE.

The emission layer of the functional layers EL may be patterned to correspond to the emission area EA. The hole control layer and the electron control layer of the functional layer EL may be provided as common layers across the plurality of pixels PX (see FIG. 4). However, an embodiment of the disclosure is not limited to this arrangement. The hole control layer and the electron control layer may be patterned to correspond to the emission area EA, or they may overlap (e.g., partially overlap) the pixel defining layer PDL and be short-circuited. Each of the hole control layer and the electron control layer may independently include an organic material or an inorganic material.

In an embodiment, at least a portion of the functional layer EL may extend into the hole area HA. In the case where the functional layer EL extends into the hole area HA, a portion of the functional layer EL may be provided in a short-circuited form. The extended functional layer EL in the hole area HA may include at least one of the hole control layer and the electron control layer.

In an embodiment, the pixel defining layer PDL may have a single or multi-layer structure. The pixel defining layer PDL may include a polymer resin. For example, the pixel defining layer PDL may include a polyacrylate-based resin or a polyimide-based resin. The pixel defining layer PDL may also include an inorganic material in addition to the polymer resin. The pixel defining layer PDL may include a light absorbing material or may include a black pigment or a black dye. The pixel defining layer PDL including the black pigment or the black dye may realize a black pixel defining layer. In the case where the pixel defining layer PDL is formed, carbon black may be used as the black pigment or the black dye, but the embodiment of the disclosure is not limited to this material.

The pixel defining layer PDL may also include an inorganic material, such as silicon nitride (SiNₓ), silicon oxide (SiOₓ), silicon oxynitride (SiOₓN_{y}), or the like.

The encapsulation layer ECL may be disposed on the display element layer D-OL. The encapsulation layer ECL may be disposed on the second electrode CE of the light emitting element LD. The encapsulation layer ECL may cover the light emitting element LD. In an embodiment, the encapsulation layer ECL may be disposed on the dam pattern DMP and the grooves GV1, GV2, GV3, and GV4 in the hole area HA of the display module EDM.

The encapsulation layer ECL may include multiple encapsulation layers. The encapsulation layer ECL may include at least one inorganic layer. The encapsulation layer ECL may further include at least one organic layer. In an embodiment, the encapsulation layer ECL may include a first encapsulation layer IL1, a second encapsulation layer OL, and a third encapsulation layer IL2, which are sequentially laminated in the third direction DR3. However, an embodiment of the disclosure is not limited thereto, and the number of stacked encapsulation layers may vary. The first encapsulation layer IL1 and the third encapsulation layer IL2 may protect the display element layer D-OL from moisture and oxygen, and the second encapsulation layer OL may protect the display element layer D-OL from foreign substances such as dust particles. For example, the first and third encapsulation layers IL1 and IL2 may be inorganic encapsulation layers, and the second encapsulation layer OL may be an organic encapsulation layer.

The input sensor ISL may be disposed on the display panel DP. The input sensor ISL may be disposed directly on the encapsulation layer ECL. The input sensor ISL may include a sensor base layer 210, a first sensor conductive layer 220, a sensor insulating layer 230, a second sensor conductive layer 240, and a sensor cover layer 250.

The sensor base layer 210 may be directly disposed on the display panel DP. The sensor base layer 210 may be an inorganic layer including at least one of silicon nitride, silicon oxynitride, or silicon oxide. In another embodiment, the sensor base layer 210 may be an organic layer including an epoxy resin, an acrylic resin, or an imide-based resin. Each of the sensor base layer 210 may have a single-layer structure or a multi-layer structure in which multiple layers are laminated in the third direction DR3.

Each of the first sensor conductive layer 220 and the second sensor conductive layer 240 may have a single-layer structure or a multi-layer structure in which multiple layers are laminated in the third direction DR3.

The conductive layer having the single-layer structure may include a metal layer or a transparent conductive layer. The metal layer may include molybdenum, silver, titanium, copper, aluminum, or an alloy thereof. The transparent conductive layer may include a transparent conductive oxide such as indium tin oxide, indium zinc oxide, zinc oxide, or indium zinc tin oxide. The transparent conductive layer may include conductive polymers such as PEDOT, metal nanowires, graphene, and the like.

The conductive layer having a multi-layer structure may include metal layers. The metal layers may have a three-layer structure of titanium/aluminum/titanium. The conductive layer having a multi-layer structure may combine at least one metal layer with at least one transparent conductive layer.

The sensor insulating layer 230 may be disposed between the first sensor conductive layer 220 and the second sensor conductive layer 240. The sensor cover layer 250 may be disposed on the sensor insulating layer 230 and may cover the second sensor conductive layer 240. The second sensor conductive layer 240 may include a conductive pattern. The sensor cover layer 250 may cover the conductive pattern and may reduce or eliminate the likelihood of damage to the conductive pattern in a subsequent process.

Each of the sensor insulating layer 230 and the sensor cover layer 250 may include an inorganic layer. The inorganic layer may include at least one of aluminum oxide, titanium oxide, silicon oxide, silicon nitride, silicon oxynitride, zirconium oxide, or hafnium oxide.

The sensor insulating layer 230 and the sensor cover layer 250 may each include an organic layer. The organic layer may include at least one of an acrylate-based resin, a methacrylate-based resin, a polyisoprene-based resin, a vinyl-based resin, an epoxy-based resin, a urethane-based resin, a cellulose-based resin, a siloxane-based resin, a polyimide-based resin, a polyamide-based resin, or a perylene-based resin.

Referring to FIGS. 4 and 6, a module hole HH may be defined in the display module EDM, and the display module EDM may include a hole area HA, which includes the module hole HH that is defined to penetrate through the display module EDM. The module hole HH may be defined to pass through the display module EDM and may be bordered by an exposed sidewall DM-HS of the display module EDM.

The display module EDM may include multiple dam parts DM1, DM2, DM3, and DM4 disposed in the hole area HA. These dam parts DM1, DM2, DM3, and DM4 may protect the display element layer D-OL during the process of forming the module hole HH. For example, the dam parts DM1, DM2, DM3, and DM4 may prevent physical impacts, such as cracks that may occur when forming the module hole HH, from affecting the display area AA. The dam parts DM1, DM2, DM3, and DM4 may prevent chemical materials used in processing of the display module EDM, such as forming of the module hole HH, from penetrating into the display area AA. The dam parts DM1, DM2, DM3, and DM4 may function to prevent a flow of a resin composition when an excessive amount of resin composition is applied during the formation of the encapsulation layer ECL.

In FIGS. 4 and 6, four dam parts DM1, DM2, DM3, and DM4 are illustrated as an example, but this embodiment is not limited thereto. The number of dam parts may vary and could be 3 or fewer, or 5 or more.

The dam parts DM1, DM2, DM3, and DM4 may be disposed on the base layer BS. In an embodiment, the dam parts DM1, DM2, DM3, and DM4 may be disposed on a lower insulating layer LIL. The lower insulating layer LIL may include the first to fourth insulating layers 10, 20, 30, and 40 described in FIG. 5.

Referring to FIGS. 4 and 6, the display module EDM according to an embodiment may include first to fourth dam parts DM1, DM2, DM3, DM4 surrounding the module hole HH and disposed in the hole area HA. The first dam part DM1 may be disposed adjacent to the display area AA. The first dam part DM1 may be disposed to surround the second dam part DM2. The second dam part DM2 may be disposed to surround the third dam part DM3, and the third dam part DM3 may be disposed to surround the fourth dam part DM4. The display module EDM may include a third dam part DM3 disposed surrounding the fourth dam part DM4. In an embodiment, the display module EDM may further include a first dam part DM1 that surrounds the second dam part DM2 and is adjacent to the display area AA.

In the hole area HA, the first groove GV1 may be defined between the display area AA and the first dam part DM1. The first groove GV1 may be defined adjacent to the first dam part DM1. In the display module EDM according to an embodiment, the first groove GV1 may be defined between a portion of the display panel DP, which is disposed at the boundary between the display area AA and the hole area HA, and the first dam part DM1.

The second groove GV2 may be defined between the first dam part DM1 and the second dam part DM2, the third groove GV3 may be defined between the second dam part DM2 and the third dam part DM3, and the fourth groove GV4 may be defined between the third dam part DM3 and the fourth dam part DM4.

Each of the dam parts DM1, DM2, DM3, and DM4 may include multiple dam layers laminated in the third direction DR3, which corresponds to a thickness direction. The first dam part DM1 and the second dam part DM2 may include first dam layers DM1-B and DM2-B, second dam layers DM1-T and DM2-T, and third dam layers DM1-A and DM2-A, respectively. The third dam part DM3 and the fourth dam part DM4 may include first dam layers DM3-B and DM4-B and second dam layers DM3-T and DM4-T, respectively. The second dam layers DM1-T, DM2-T, DM3-T, and DM4-T may be disposed on the first dam layers DM1-B, DM2-B, DM3-B, and DM4-B, respectively. The third dam layers DM1-A and DM2-A may be disposed on the second dam layers DM1-T and DM2-T, respectively.

In an embodiment, the first dam layers DM1-B, DM2-B, DM3-B, and DM4-B may be disposed on the same layer as the first insulating layer 50, and the second dam layers DM1-T, DM2-T, DM3-T, and DM4-T may be disposed on the same layer as the second insulating layer 60. For example, the first dam layers DM1-B, DM2-B, DM3-B, and DM4-B may be formed in the same process as the first insulating layer 50, and the second dam layers DM1-T, DM2-T, DM3-T, and DM4-T may be formed in the same process as the second insulating layer 60. In an embodiment, each of the first dam layers DM1-B, DM2-B, DM3-B, and DM4-B may be an organic layer made of the same material as the first insulating layer 50, and each of the second dam layers DM1-T, DM2-T, DM3-T, and DM4-T may be an organic layer made of the same material as the second insulating layer 60. The third dam layers DM1-A and DM2-A may be formed in the same process as the pixel defining layer PDL. However, the embodiment of the disclosure is not limited to these configurations.

In FIG. 6, each of the first dam part DM1 and the second dam part DM2 may include three dam layers, and each of the third dam part DM3 and the fourth dam part DM4 may include two dam layers, but are not limited thereto. At least one of the first dam part DM1 and the second dam part DM2 may include two dam layers or may include only one dam layer, and at least one of the third dam part DM3 and the fourth dam part DM2 may include three or more dam layers, only one dam layer, or any number of dam layers.

In an embodiment, each of the first dam layers DM1-B, DM2-B, DM3-B, and DM4-B, the second dam layers DM1-T, DM2-T, DM3-T, and DM4-T, and the third dam layers DM1-A and DM2-A may have an inclined side surface. However, an embodiment of the disclosure is not limited to the illustrated structure; each of the dam layers may independently have at least partially curved surfaces.

The display module EDM may further include inorganic dams IOP disposed in the hole area HA. In FIG. 6, two inorganic dams IOP may be illustrated adjacent to the module hole HH, but this embodiment is not limited to this arrangement; some inorganic dams IOP may be omitted, or additional inorganic dams may be included.

In an embodiment, each of the inorganic dams IOP may include a first layer IOL1 and a second layer IOL2. The first layer IOL1 may include the same material as the first lower insulating layer 10 and may be formed through the same process as the first lower insulating layer 10. The second layer IOL2 may include the same material as the second lower insulating layer 20 and may be formed through the same process as the second lower insulating layer 20. However, this is merely an example, and the configuration of the layers constituting each of the inorganic dams IOP may be modified in various ways. A width of the first layer IOL1 may be greater than that of the second layer IOL2, resulting in a stepped shape for each inorganic dam IOP.

Referring to FIGS. 5 and 6, the encapsulation layer ECL may cover the display element layer D-OL and the exposed circuit layer D-CL. In the display area AA, the encapsulation layer ECL may cover the light emitting element LD and the pixel defining layer PDL. In the hole area HA, the encapsulation layer ECL may cover an exposed portion of the display element layer D-OL, an exposed portion of the circuit layer D-CL, the dam parts DM1, DM2, DM3, and DM4, and the inorganic dams IOP.

The first encapsulation layer IL1 of the encapsulation layer ECL may be disposed on the second electrode CE. In an embodiment, the first encapsulation layer IL1 may be directly disposed on the second electrode CE. In an embodiment of the display device, in the case where the light emitting element LD further includes a capping layer (not shown) disposed on the second electrode CE, the first encapsulation layer IL1 may be directly disposed on the capping layer.

The first encapsulation layer IL1 may be disposed on the dam parts DM1, DM2, DM3, and DM4, as well as the grooves GV1, GV2, GV3, and GV4. The first encapsulation layer IL1 may protect components of the display panel DP from moisture and oxygen outside the display panel DP.

The first encapsulation layer IL1 may cover all of the first to fourth grooves GV1, GV2, GV3, and GV4. The second encapsulation layer OL may be disposed on the first encapsulation layer IL1, overlapping at least some of the first to fourth grooves GV1, GV2, GV3, and GV4. For example, the second encapsulation layer OL may overlap the first and second grooves GV1 and GV2. The third encapsulation layer IL2 may be disposed on the second encapsulation layer OL, covering all of the first to fourth grooves GV1, GV2, GV3, and GV4. In a portion of the hole area HA, the third encapsulation layer IL2 may be directly disposed on the first encapsulation layer IL1.

The display module EDM according to an embodiment may include a protrusion pattern MTP and an anti-deposition pattern WAL that overlaps the protrusion pattern MTP. The anti-deposition pattern WAL may overlap at least a portion of the protrusion pattern MTP.

The protrusion pattern MTP may be disposed between the dam layers in each of the dam parts DM1, DM2, DM3, and DM4. In an embodiment, the protrusion pattern MTP may be disposed between the first dam layers DM1-B, DM2-B, DM3-B, DM4-B and the second dam layers DM1-T, DM2-T, DM3-T, and DM4-T. However, this is merely an example, and the protrusion pattern MTP may be disposed on one of the lower insulating layers LIL or may be included in the base layer BS in the case where the base layer BS has a structure in which multiple layers are laminated.

A width of the protrusion pattern MTP in a direction may be greater than that of each of the first dam layers DM1-B, DM2-B, DM3-B, and DM4-B in the same direction. Thus, at least a portion of the protrusion pattern MTP may extend outward from the dam layers toward the grooves GV1, GV2, GV3, and GV4. At least a portion of the protrusion pattern MTP may include a tip part TP that extends into each of the grooves GV1, GV2, GV3, and GV4. In an embodiment, the tip part TP may not overlap the first dam layers DM1-B, DM2-B, DM3-B, and DM4-B or the second dam layers DM1-T, DM2-T, DM3-T, and DM4-T. For example, in an embodiment, the tip part TP may not overlap the first insulating layer 50, which serves as each of the first dam layers DM1-B, DM2-B, DM3-B, and DM4-B or the second insulating layer 60, which serves as each of the second dam layers DM1-T, DM2-T, DM3-T, and DM4-T. Hereafter, each of the first dam layers DM1-B, DM2-B, DM3-B, and DM4-B may be referred to as the first insulating layer, and each of the second dam layers DM1-T, DM2-T, DM3-T, and DM4-T may be referred to as the second insulating layer.

In an embodiment, the protrusion pattern MTP may be formed in the same process as one of the conductive patterns of the circuit layer D-CL disposed in the display area AA. For example, the protrusion pattern MTP may be formed in the same process as the second connection electrode CNE2. Specifically, the protrusion pattern MTP may be formed of the same material as the second connection electrode CNE2. However, the embodiment of the disclosure is not limited thereto.

In an embodiment, the protrusion pattern MTP may be disposed between the base layer BS and the first electrode AE, which serves as a pixel electrode. The protrusion pattern MTP may define a pattern hole PTH. The pattern hole PTH may be defined by the tip part TP of the protrusion pattern MTP. In an embodiment, the pattern hole PTH may surround the module hole HH.

Referring to FIGS. 6 and 7, a first opening OP-B may overlap the pattern hole PTH and be defined in the first insulating layer 50 or the first dam layers DM1-B, DM2-B, DM3-B, and DM4-B. The first dam layers DM1-B, DM2-B, DM3-B, and DM4-B, or the first insulating layer 50 may be disposed between the base layer BS and the protrusion pattern MTP. The first opening OP-B may also be referred to as a lower opening.

A second opening OP-T may overlap the pattern hole PTH and be defined in the second insulating layer 60 or the second dam layers DM1-T, DM2-T, DM3-T, and DM4-T. The second dam layers DM1-T, DM2-T, DM3-T, and DM4-T, or the second insulating layer 60 may be disposed between the protrusion pattern MTP and the pixel electrode AE. The second opening OP-T may also be referred to as an upper opening.

The first opening OP-B (lower opening), the pattern hole PTH, and the second opening OP-T (upper opening) may overlap each other in the third direction DR3, which corresponds to the thickness direction. In an embodiment, each of a width W_{BOP} of the first opening OP-B and a width W_{TOP} of the second opening OP-T, both measured in a direction, may be greater than a width W_{PTH} of the pattern hole PTH in the same direction. The width W_{BOP} of the first opening OP-B, the width W_{TOP} of the second opening OP-T, and the width W_{PTH} of the pattern hole PTH may be defined as average widths in the first opening OP-B, the second opening OP-T, and the pattern hole PTH, respectively.

In an embodiment, the first groove GV1 may include a pattern hole PTH, a first opening OP-B overlapping the pattern hole PTH and defined below the pattern hole PTH, and a second opening OP-T overlapping the pattern hole PTH and defined above the pattern hole PTH. The first groove GV1 may further include a third opening OP-A. The third opening OP-A may overlap the pattern hole PTH and be defined above the second opening OP-T. The third opening OP-A may be defined in the pixel defining layer PDL or the third dam layers DM1-A and DM2-A. FIG. 7 illustrates a schematic enlarged view of a portion YY′, which is a portion where the first groove GV1 is defined. However, the laminated structure of the protrusion pattern MTP and the anti-deposition pattern WAL, along with the structures of the first opening OP-B, the pattern hole PTH, and the second opening OP-T, as shown in FIG. 7, may also apply to the second to fourth grooves GV2, GV3, and GV4 and their adjacent portions.

In an embodiment, the anti-deposition pattern WAL may be directly disposed on a bottom surface BS_MT of the protrusion pattern MTP. Referring to FIGS. 6 and 7, in the display module EDM according to an embodiment, the anti-deposition pattern WAL may entirely overlap the protrusion pattern MTP.

The anti-deposition pattern WAL may be formed of a material having low surface energy. The anti-deposition pattern WAL may include a material having low surface energy and may have a water contact angle of greater than or equal to about 110°. The anti-deposition pattern WAL may include a fluorine (F)-based compound.

In an embodiment, the anti-deposition pattern WAL may include an aromatic hydrocarbon compound. The aromatic hydrocarbon compound may contain at least one fluorine substituent. The aromatic hydrocarbon compound may include a core part containing at least one substituted or unsubstituted aromatic ring, and at least one of a fluorine atom or a fluorine substituent bonded to the core part.

The core part of the aromatic hydrocarbon compound may include about 1 to 5 aromatic rings, and the aromatic ring may be an aryl ring or heteroaryl ring. The aromatic ring may be a benzene ring, or a heterocycle containing O, N, or S as a ring forming atom. In the case where the core part includes multiple aromatic rings, the aromatic rings may connect to each other by a single bond, or at least one aromatic ring may be fused with another aromatic ring. In an embodiment, a molecular weight of the core part may be less than or equal to about 300 Da. At least one hydrogen atom of the aromatic ring in the core part may be replaced with a fluorine atom.

The aromatic hydrocarbon compound may include at least one of the fluorine atom or the fluorine substituent, and the fluorine atom may be directly substituted on the aromatic ring. The fluorine substituent may be bonded to the aromatic ring. The fluorine substituent may be represented by *—(CF₂)ₙ—CF₃, where n may be an integer of greater than or equal to 1 and less than or equal to 9. The molecular weight of the aromatic hydrocarbon compound may be greater than or equal to about 500 Da and less than or equal to about 2,000 Da. Since the aromatic hydrocarbon compound has a molecular weight of greater than or equal to about 500 Da and less than or equal to about 2,000 Da, the anti-deposition pattern WAL may be easily manufactured to have a specific pattern.

The anti-deposition pattern WAL may be manufactured by thermally depositing the aromatic hydrocarbon compound. The anti-deposition pattern WAL may be formed using a vacuum thermal evaporation method to deposit the aromatic hydrocarbon compound.

The material of the anti-deposition pattern WAL is not limited to the aromatic hydrocarbon compound described above, and any material that exhibits low surface energy characteristics suitable for preventing the deposition of the second electrode CE may be used without limitation.

For example, in an embodiment, the anti-deposition pattern WAL may be formed as a self-assembled monolayer. The self-assembled monolayer may include a head portion, a tail portion, and a functional end portion. In the case of the self-assembled monolayer material that is capable of being used as the anti-deposition pattern WAL, the head portion may include a functional group that has excellent bonding ability to the protrusion pattern MTP, and the functional end portion may include a fluorine-based functional group.

The anti-deposition pattern WAL may be disposed directly beneath the protrusion pattern MTP, and the pattern hole PTH may be defined by the protrusion pattern MTP and the anti-deposition pattern WAL. The anti-deposition pattern WAL may overlap the tip part TP.

In an embodiment, the second electrode CE may be physically disconnected by the anti-deposition pattern WAL. The second electrode CE may not be deposited on the anti-deposition pattern WAL. Due to the low surface energy of the anti-deposition pattern WAL, the second electrode CE may not be provided to the anti-deposition pattern WAL, and as a result, the second electrode CE may be cut off and separated by the anti-deposition pattern WAL.

The second electrode CE may include a first portion CE-a and a second portion CE-b, which are disconnected and separated by the anti-deposition pattern WAL. The first portion CE-a may be disposed in the first opening OP-B, and the second portion CE-b may be disposed in the second opening OP-T. The second portion CE-b, which is a portion of the second electrode CE, may be disposed above the tip part TP, and the first portion CE-b, which is a portion of the second electrode CE, may be disposed below the tip part TP.

The second electrode CE may not cover the anti-deposition pattern WAL exposed in the first groove GV1. The bottom surface BS_WA of the anti-deposition pattern WAL may not be covered by the second electrode CE. A side surface of the anti-deposition pattern WAL, which is adjacent to a side surface of the protrusion pattern MTP that defines the pattern hole PTH, may also not be covered by the second electrode CE. Due to the low surface energy of the anti-deposition pattern WAL, the second electrode CE may not be disposed at a portion at which the anti-deposition pattern WAL is exposed, and the second electrode CE may be disconnected with the exposed anti-deposition pattern WAL therebetween.

In an embodiment, the functional layer EL beneath the second electrode CE may also be cut off by the anti-deposition pattern WAL. The functional layer EL may include a third portion EL-a and a fourth portion EL-b, which are disconnected and separated by the anti-deposition pattern WAL. The third portion EL-a may be disposed in the first opening OP-B, and the fourth portion EL-b may be disposed in the second opening OP-T. The fourth portion EL-b, which is a portion of the functional layer EL, may be disposed above the tip part TP, and the third portion EL-a, which is a portion of the functional layer EL, may be disposed below the tip part TP. In an embodiment, the functional layer EL may not cover the anti-deposition pattern WAL exposed in the first groove GV1, and the functional layer EL may be disconnected with the exposed anti-deposition pattern WAL therebetween.

In an embodiment, the encapsulation layer ECL may be disposed on the second electrode CE. As illustrated in FIGS. 6 and 7, in an embodiment, the encapsulation layer ECL may cover at least a portion of the exposed anti-deposition pattern WAL that is not covered by the second electrode CE. The encapsulation layer ECL may be in contact with the anti-deposition pattern WAL at the portion at which the second electrode CE is absent. In an embodiment, the first encapsulation layer IL1 may cover the pattern hole PTH and the anti-deposition pattern WAL exposed in the first opening OP-B. The first encapsulation layer IL1 may be directly disposed on a bottom surface BS_WA of the anti-deposition pattern WAL.

The display device according to an embodiment may include the anti-deposition pattern disposed directly below the protrusion pattern, which extends into the groove in the hole area HA adjacent to the portion at which the module hole HH is defined, and thus, at least a portion of the second electrode CE (cathode) may be disconnected in the hole area HA. Thus, the second electrode CE may be continuously disposed in the hole area HA without extending into the display area AA, thereby preventing the second electrode CE from serving as a passage through which the moisture or gas moves. Thus, the display device according to an embodiment including the anti-deposition pattern in the hole area in which the groove is defined may exhibit excellent reliability characteristics.

The display device according to an embodiment may exhibit excellent reliability characteristics by preventing the migration of moisture or gas through the second electrode, and the second electrode may be formed to have a high Ag content, thereby providing excellent electrical characteristics and display quality.

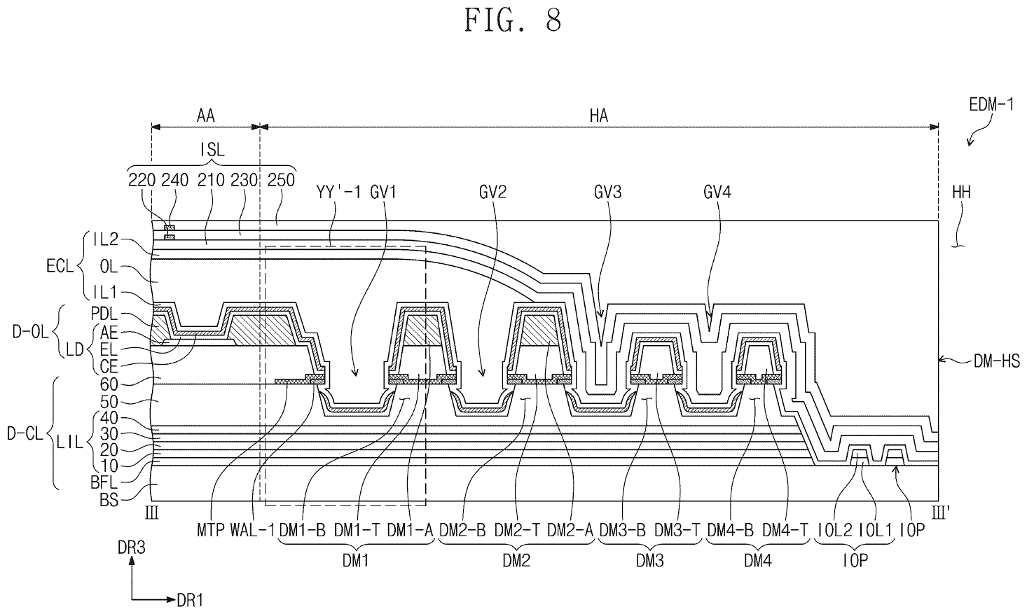

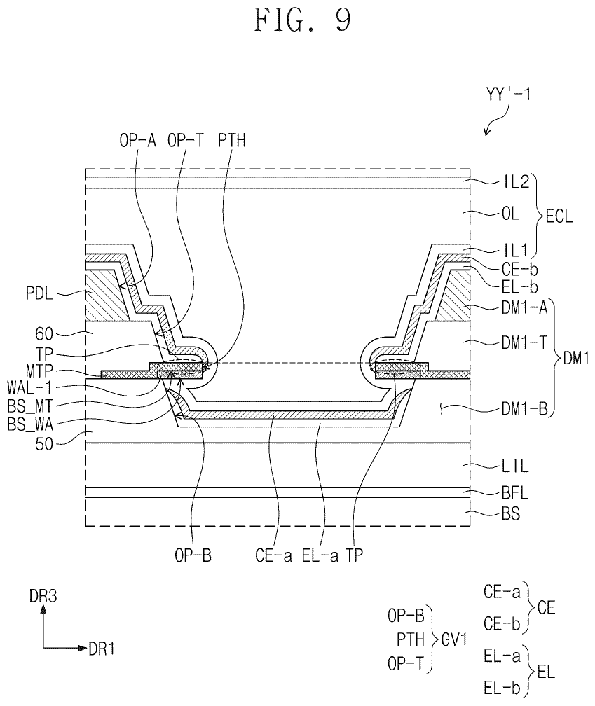

FIG. 8 is a schematic cross-sectional view illustrating a portion of the display module according to an embodiment of the disclosure. FIG. 9 is a schematic enlarged view illustrating a portion of the display module according to an embodiment of the disclosure. FIG. 8 is a portion corresponding to line III-III′ of FIG. 4, and FIG. 9 is a schematic enlarged view of an area YY′-1 of FIG. 8. FIGS. 8 and 9 illustrate a portion of the hole area HA (see FIG. 4).

In the description in FIGS. 8 and 9, contents that overlap those descriptions provided with reference to FIGS. 1 to 7 will not be repeated, and differences will be mainly described. A display module EDM-1 according to an embodiment illustrated in FIGS. 8 and 9 is different from the display module EDM according to an embodiment described with reference to FIGS. 6 and 7 in an arrangement of an anti-deposition pattern WAL.

When compared to the anti-deposition pattern WAL according to an embodiment described with reference to FIGS. 6 and 7, the display module EDM-1 according to the embodiment illustrated in FIGS. 8 and 9 may include an anti-deposition pattern WAL-1 that may overlap only a partial area of the protrusion pattern MTP. In an embodiment, at least a portion of the protrusion pattern MTP may not overlap the anti-deposition pattern WAL.

The anti-deposition pattern WAL-1 may overlap the tip part TP of the protrusion pattern MTP. The anti-deposition pattern WAL-1 may be placed to define the pattern hole PTH and cover the bottom surface BS-MT of the tip part TP, which protrudes into the first groove GV1, ensuring that the second electrode CE remains disconnected rather than continuous.

A bottom surface BS_WA of the anti-deposition pattern WAL-1 may not be covered by the second electrode CE. The encapsulation layer ECL may be in contact with the anti-deposition pattern WAL-1 at a portion at which the second electrode CE is not present. In an embodiment, the first encapsulation layer IL1 may cover the pattern hole PTH and the anti-deposition pattern WAL-1 exposed in the first opening OP-B. The first encapsulation layer IL1 may be directly disposed on the bottom surface BS_WA of the anti-deposition pattern WAL-1.

Even in the display device that includes the display module EDM-1 according to the embodiment illustrated in FIGS. 8 and 9, at least a portion of the second electrode CE (cathode) may be disconnected in the hole area HA by the anti-deposition pattern WAL-1. Thus, the display device according to an embodiment including the anti-deposition pattern in the hole area where the groove is defined may exhibit excellent reliability characteristics by preventing the second electrode CE from function as a passage for moisture or gas. The display device according to an embodiment may exhibit excellent reliability characteristics by blocking the movement of moisture or gas through the second electrode, and the second electrode, which may be formed with a high Ag content, can provide excellent electrical characteristics and display quality.

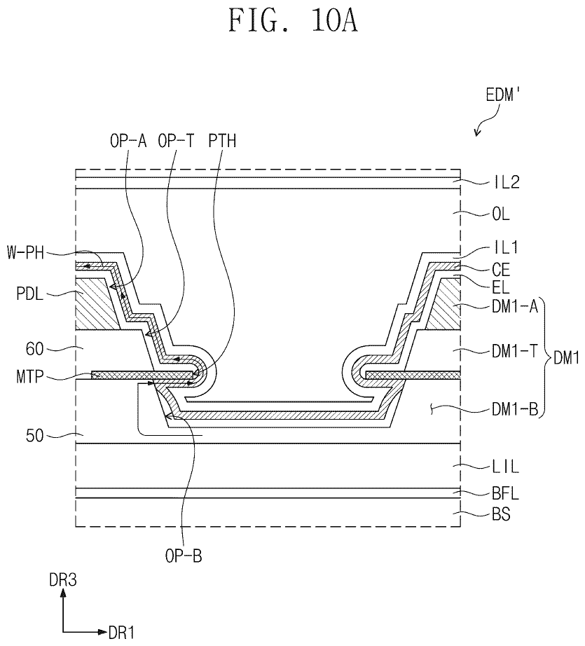

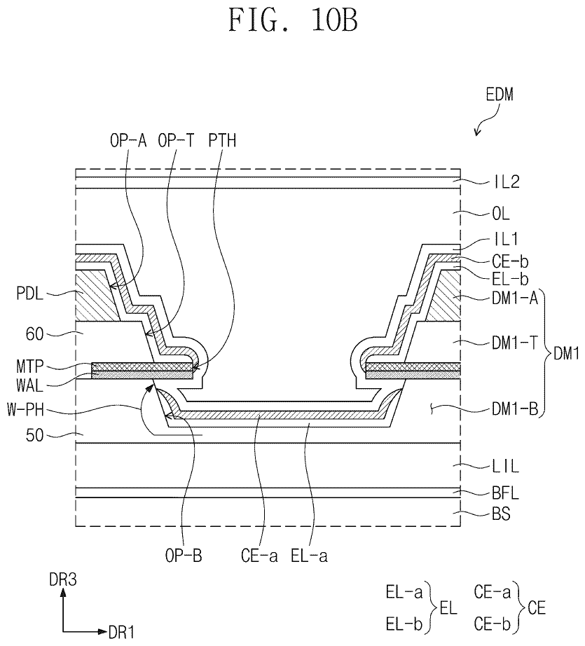

FIG. 10A is a schematic view illustrating a movement path of moisture or as in a display module according to the related art, and FIG. 10B is a schematic view illustrating a movement path of moisture or gas in a display module according to an embodiment of the disclosure.

Referring to FIG. 10A, in the case of a display module EDM′ according to the related art, a second electrode CE may not be disconnected even around a protrusion pattern MTP that defines a pattern hole PTH, but be provided integrally with the entire first opening OP-B and second opening OP-T. The second electrode CE may serve as a movement path W-PH for moisture or gas. In the case of moisture or gas moving along the second electrode CE, the moisture or gas may be transferred into a display area AA, and as a result, reliability of the light emitting element in the display area AA may be reduced, leading to deterioration in light efficiency and display quality.

In contrast, the display module EDM according to an embodiment illustrated in FIG. 10B may include the anti-deposition pattern WAL disposed to overlap the protrusion pattern MTP, where the second electrode CE may be disconnected and separated into a first portion CE-a and a second portion CE-b due to the exposed portion of the anti-deposition pattern WAL, which is not covered by the protrusion pattern MTP or the first and second insulating layers 50 and 60. The functional layer EL may also be separated into a third portion EL-a and a fourth portion EL-b by the anti-deposition pattern WAL. Thus, the moisture or gas that enters through the insulating layer 50 or the first dam layer DM1-B may encounter a disconnected second electrode CE. This disconnection interrupts the movement path W-PH for moisture or gas, preventing its transfer to the display area AA along the second electrode CE. Thus, in the case of the embodiment including the anti-deposition pattern WAL may demonstrate the excellent reliability characteristics not only at room temperature but also under extreme conditions such as high temperature and high humidity. In an embodiment, the display device includes the anti-deposition pattern WAL, where the second electrode CE is disconnected around the anti-deposition pattern WAL. This configuration prevents moisture or gas from permeating, even under conditions of high temperature and high humidity, thereby enhancing the reliability of the pixels in the display area and preventing accelerated deformation or shrinkage of the emission area EA (FIG. 5).

FIG. 10B illustrates the structure of the display module according to an embodiment described with reference to FIGS. 6 and 7 to explain how the movement path W-PH for moisture or gas is disconnected. However, this effect may be similarly observed in the structure of the display module according to the embodiment described with reference to FIGS. 8 and 9, as well as other structures where the second electrode is not continuous but includes a disconnected portion due to the presence of the anti-deposition pattern.

The display device according to an embodiment may exhibit excellent device efficiency and low touch noise characteristics, as the second electrode (counter electrode) is made from a high-content Ag metal material. Table 1 below shows a comparison of luminous efficiency and touch noise characteristics between a comparative example and an embodiment. The luminous efficiency was evaluated based on CIE y color coordinates, and the touch noise was measured as a peak-to-peak noise value for a signal. In Table 1, the comparative example corresponds to a display device that contains AgMg for the second electrode, which was manufactured using a thermal evaporation. The embodiment corresponds to a display device that contains a high content of Ag, does not contain Mg, and includes a second electrode manufactured using the sputtering method. In the comparative example, the second electrode was manufactured to a thickness of about 95 Å, whereas in the embodiment, the second electrode was manufactured to a thickness of about 97 Å.

TABLE 1

| | Luminous efficiency | |
|---|---|---|
| Classification | (cd/A/y) | Touch noise (peak-to-peak) |
| Comparative | 133.2 | 750 |
| example | | |
| Embodiment | 133.5 | 600 |

Referring to the results in Table 1, the embodiment demonstrated excellent luminous efficiency characteristics compared to the comparative example, and the touch noise was reduced by about 20%, indicating excellent touch performance. It is confirmed that the embodiment including a second electrode made of high-content Ag exhibits outstanding efficiency and touch performance.

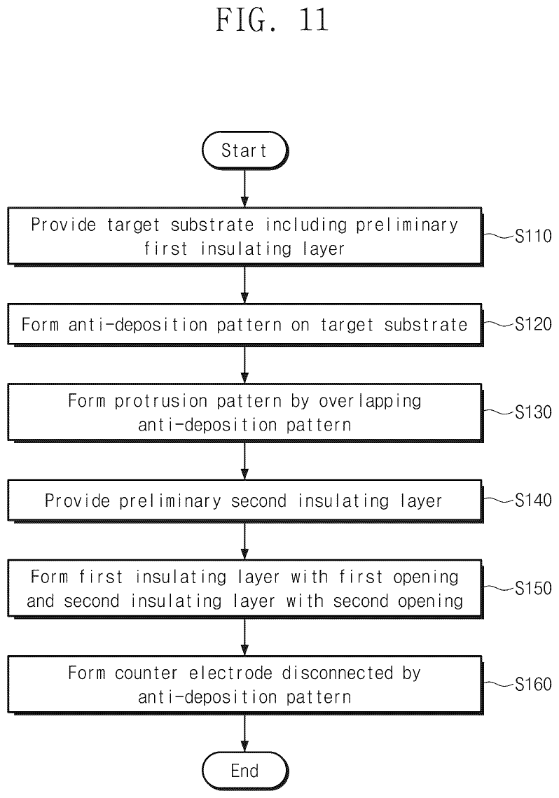

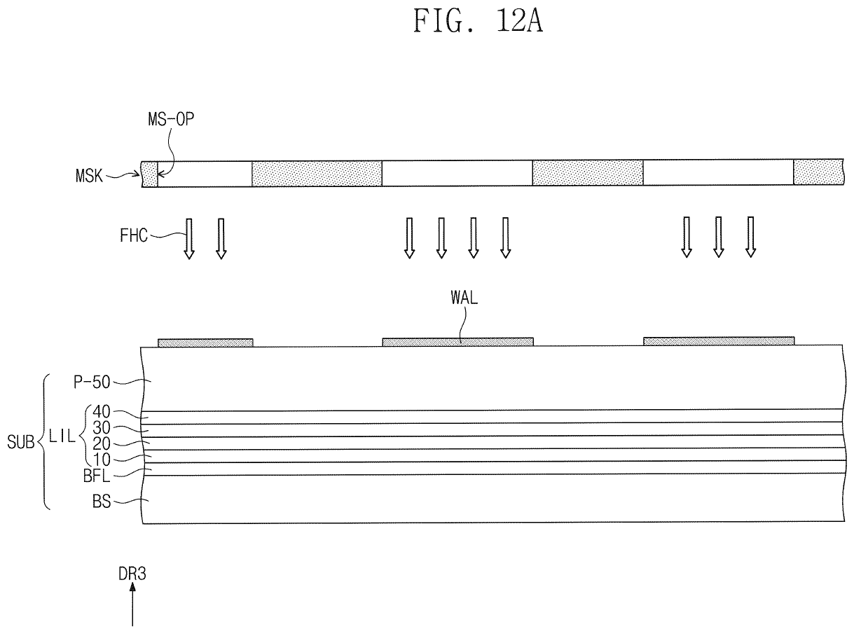

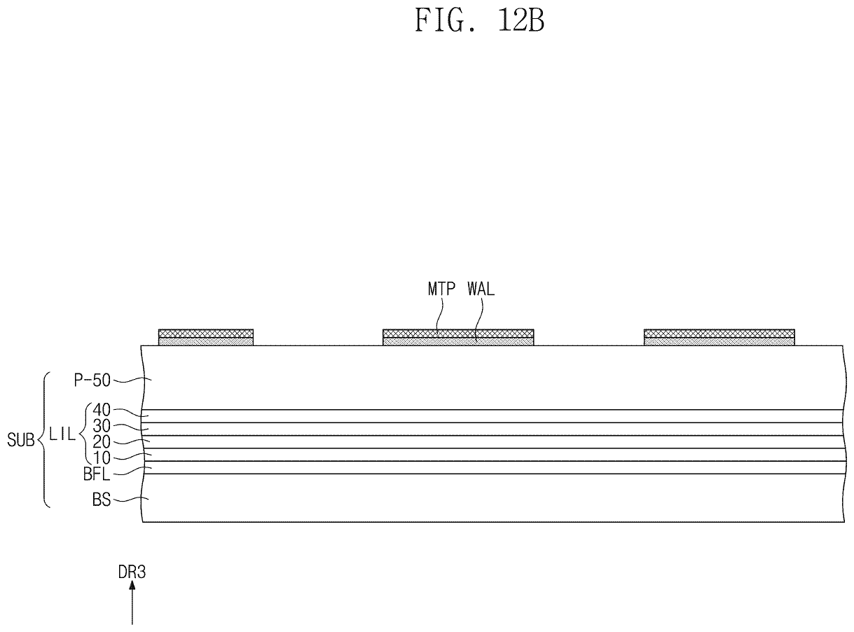

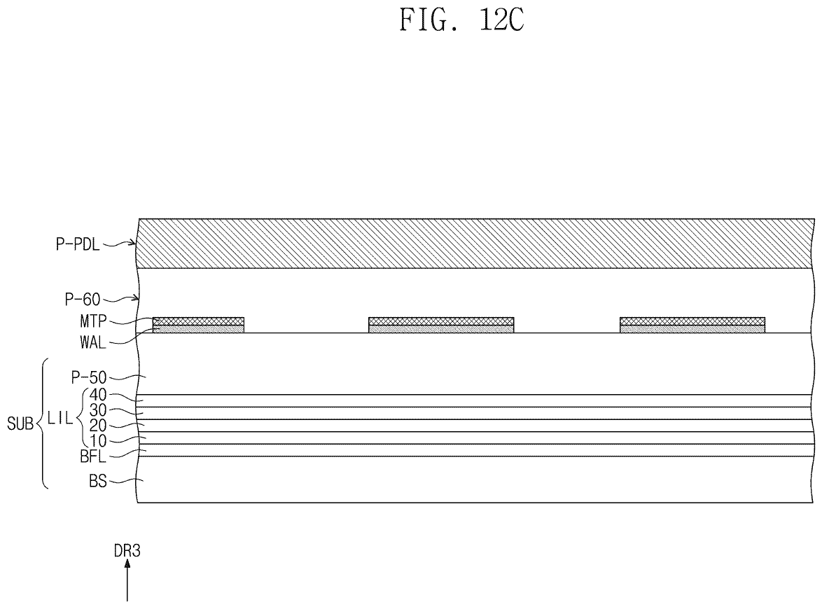

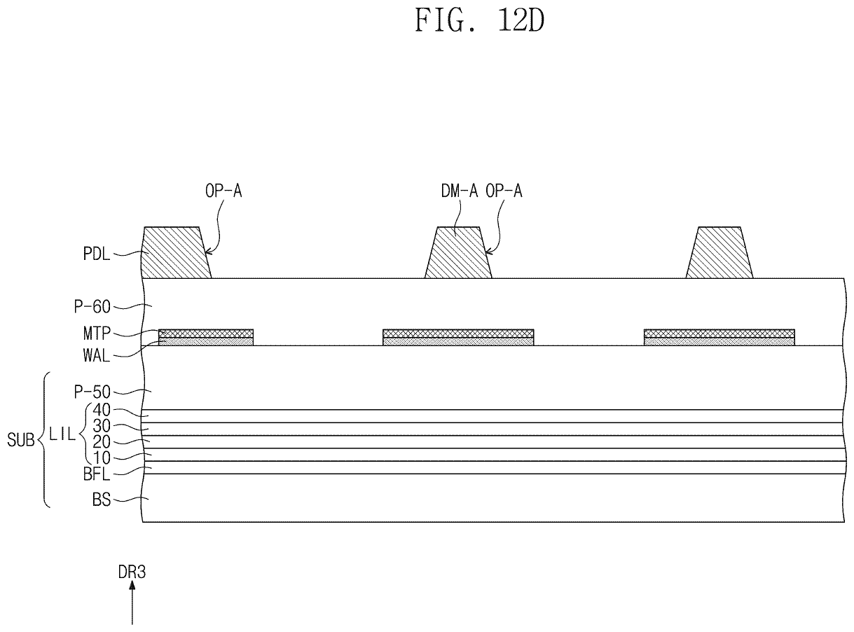

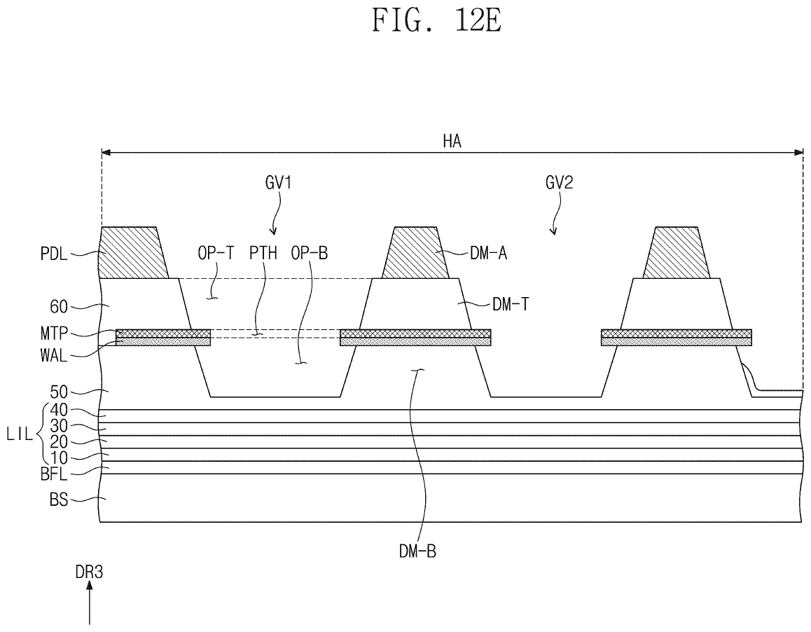

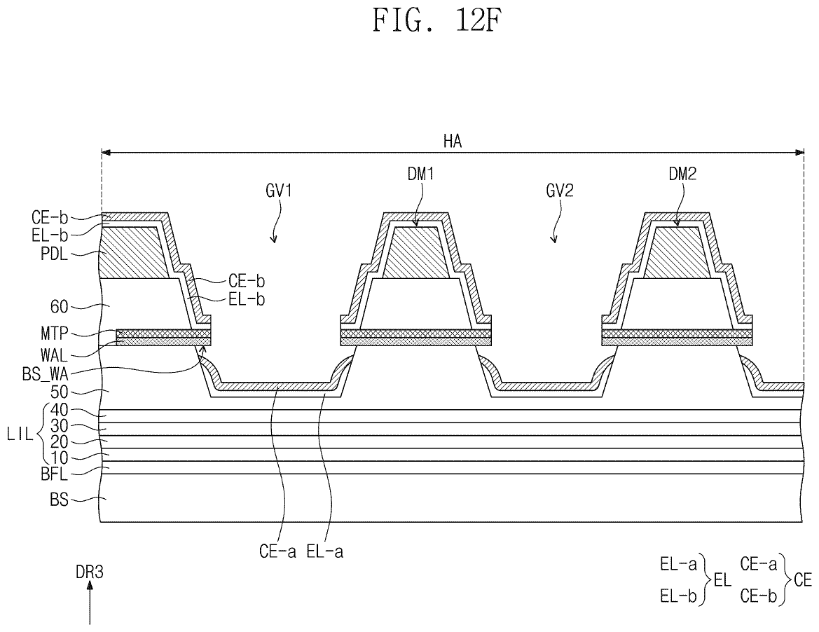

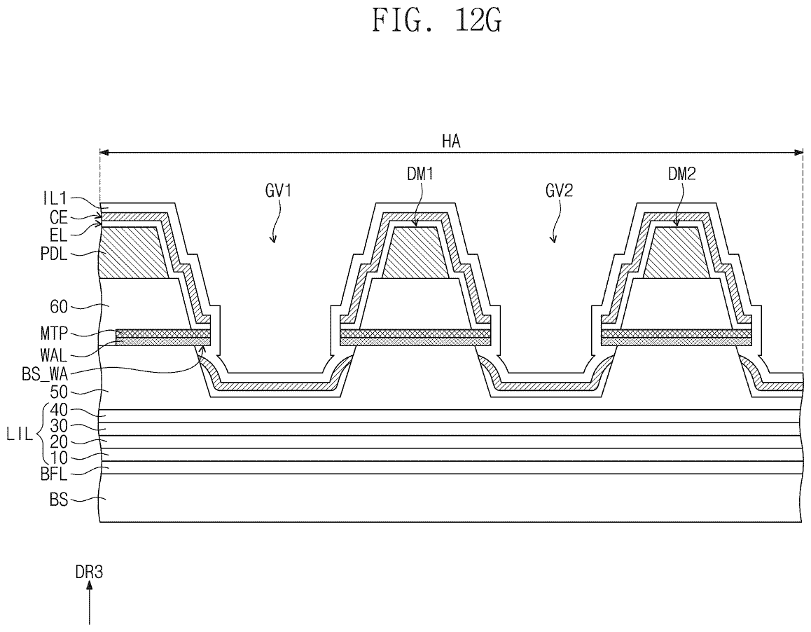

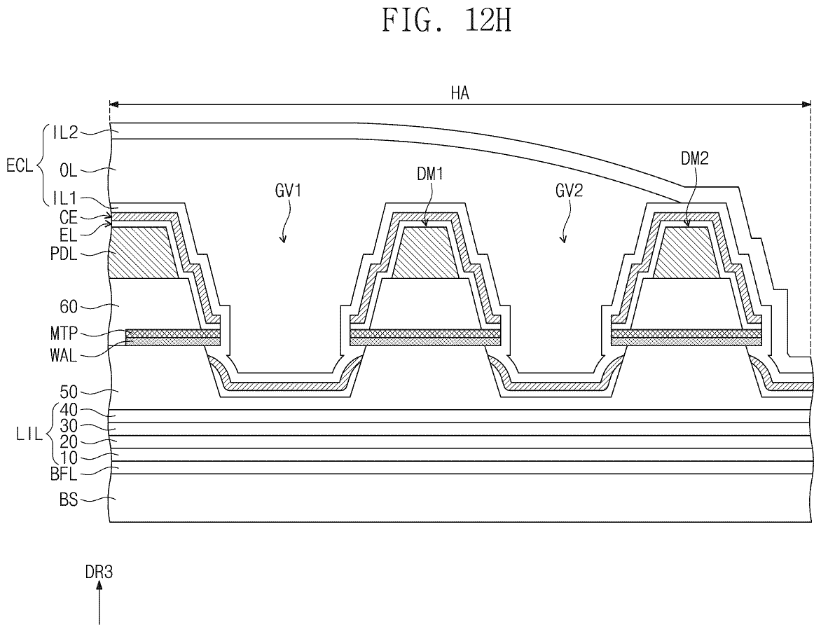

Hereinafter, a method for manufacturing a display device according to an embodiment will be described with reference to FIGS. 11 to 12H. FIG. 11 is a schematic flowchart illustrating a method for manufacturing a display device according to an embodiment of the disclosure. FIGS. 12A to 12H are schematic views sequentially illustrating processes in the method for manufacturing the display device according to an embodiment of the disclosure. FIGS. 12A to 12H illustrate a portion of the hole area HA (see FIG. 4). In the description of the method for manufacturing the display device according to an embodiment described below with reference to FIGS. 11 to 12H, the same description may be applied to the same components as the components of the display device described with reference to FIGS. 1 to 9.

The method for manufacturing the display device according to an embodiment may include a process (S110) of providing a target substrate including a preliminary first insulating layer, a process (S120) of forming an anti-deposition pattern on the target substrate, a process (S130) of forming a protrusion pattern by overlapping the anti-deposition pattern, a process (S140) of providing a preliminary second insulating layer, a process (S150) of forming a first insulating layer, in which a first opening is defined, and a second insulating layer, in which a second opening is defined, and a process (S160) of forming a counter electrode that is disconnected by the anti-deposition pattern.

FIG. 12A illustrates an example of the process (S120) of forming the anti-deposition pattern after the process (S110) of providing the target substrate.

The target substrate SUB may include a base layer BS and a preliminary first insulating layer P-50. The target substrate SUB may refer to a portion that serves as a support member for the anti-deposition pattern WAL. In an embodiment illustrated in FIG. 12A and the like, the anti-deposition pattern WAL may be formed on the preliminary first insulating layer P-50. When the anti-deposition pattern WAL is formed on the preliminary first insulating layer P-50, the target substrate SUB may include a base layer BS, a preliminary first insulating layer P-50 disposed on the base layer BS, and a buffer layer BFL and a lower insulating layer LIL disposed between the base layer BS and the preliminary first insulating layer P-50. Depending on the arrangement of the anti-deposition pattern WAL, which may be disposed on one of the lower insulating layers LIL, on the buffer layer BFL, or under the buffer layer BFL, a configuration of the target substrate SUB may vary.

A position at which the anti-deposition pattern WAL is formed may vary depending on an arrangement of the protrusion pattern MTP, which will be described later. When the protrusion pattern MTP is manufactured to have a structure disposed on the first insulating layer 50, the target substrate SUB on which the anti-deposition pattern WAL is formed may be a substructure that includes the preliminary first insulating layer P-50. When the protrusion pattern MTP is manufactured to have a structure disposed on a layer other than the first insulating layer 50, the configuration of the target substrate SUB on which the anti-deposition pattern WAL is formed may also vary correspondingly.

In an embodiment, the preliminary first insulating layer P-50 may form the first insulating layer 50 (see FIG. 6) as well as the first dam layers DM1-B, DM2-B, DM3-B, and DM4-B.

The anti-deposition pattern WAL may be patterned using a mask MSK. The anti-deposition pattern WAL may be formed by depositing an aromatic hydrocarbon compound FHC through an opening area MS-OP in the mask MSK. In another embodiment, the aromatic hydrocarbon compound FHC may be deposited entirely on the target substrate SUB and then patterned using the mask MSK.

The aromatic hydrocarbon compounds FHC may be deposited by thermal evaporation. For example, the aromatic hydrocarbon compound FHC may be applied to the target substrate SUB using a vacuum thermal evaporation method. As previously described, the aromatic hydrocarbon compound FHC may include a core part including at least one substituted or unsubstituted aromatic ring, and at least one of a fluorine atom and a fluorine substituent bonded to the core part. The aromatic hydrocarbon compounds FHC may have a molecular weight of greater than or equal to about 500 Da and less than or equal to about 2,000 Da, making them suitable for thermal evaporation.

FIG. 12B illustrates an example of the process (S130) of forming the protrusion pattern. The protrusion pattern MTP may be formed to overlap the anti-deposition pattern WAL. In an embodiment, the protrusion pattern MTP and the anti-deposition pattern WAL may entirely overlap each other. However, this embodiment is not limited to that configuration, and the protrusion pattern MTP may also be formed to have a surface area greater than that of the anti-deposition pattern WAL so as to cover the anti-deposition pattern WAL.

In an embodiment, the protrusion pattern MTP may be formed in the same process as one of the components of the circuit layer D-CL (see FIG. 5). For example, in an embodiment, the protrusion pattern MTP may be formed in the same process as the second connection electrode CNE2. However, this embodiment is not limited thereto, and the protrusion pattern MTP may also be formed in a process separate from the process of forming the second connection electrode CNE2.

FIG. 12C illustrates an example of the process (S140) of providing the preliminary second insulating layer P-60. The preliminary second insulating layer P-60 may be applied to cover both the protrusion pattern MTP and the anti-deposition pattern WAL. In an embodiment, the preliminary second insulating layer P-60 may later become the second insulating layer 60 (see FIG. 6) and form the second dam layers DM1-T, DM2-T, DM3-T, and DM4-T.

A preliminary pixel defining layer P-PDL may be applied over the preliminary second insulating layer P-60. In an embodiment, the preliminary pixel defining layer P-PDL may be formed as the pixel defining layer PDL (see FIG. 6) and the third dam layers DM1-A and DM2-A.

FIG. 12D illustrates an example of the process of forming the third dam layer DM-A, which defines the third opening OP-A. The pixel defining layer PDL, which defines the light emitting opening, may also be formed together with the third dam layer DM-A. The third dam layer DM-A may be formed by performing a process such as etching after providing the preliminary pixel definition layer P-PDL.

FIG. 12E is a schematic view illustrating a process (S150) of forming a first insulating layer, which defines a first opening, and a second insulating layer, which defines a second opening. The preliminary first insulating layer P-50 may be patterned to form the first insulating layer 50, in which the first opening OP-B is defined, and the preliminary second insulating layer P-60 may be patterned to form the second insulating layer 60, in which the second opening OP-T is defined. The first insulating layer 50, formed by the patterning, may also be referred to as the first dam layer DM-B. Similarly, the second insulating layer 60, formed by the patterning, may be referred to as the second dam layer DM-T.

During the process (S150) of forming the first insulating layer with the first opening and the second insulating layer with the second opening, grooves GV1 and GV2 may be defined in the hole area HA. Each of the grooves GV1 and GV2 may include a first opening OP-B, a pattern hole PTH, and a second opening OP-T, all of which are defined to overlap each other in the third direction DR3, which is the thickness direction. An edge portion of the protrusion pattern MTP, which defines the pattern hole PTH, may protrude into the grooves GV1 and GV2. The anti-deposition pattern WAL may be disposed directly under the protrusion pattern MTP that protrudes into the grooves GV1 and GV2.

FIG. 12F is a schematic view illustrating the process (S160) of forming the counter electrode, which is disconnected by the anti-deposition pattern. The second electrode CE, serving as the counter electrode, may be disposed in the first opening OP-B and the second opening OP-T. The second electrode CE may also be disposed on the dam parts DM1 and DM2, as well as the grooves GV1 and GV2. In an embodiment, the second electrode CE may be formed by being disconnected by the anti-deposition pattern WAL. The second electrode CE may not be disposed on the bottom surface BS_WA of the anti-deposition pattern WAL. As a result, the second electrode CE may be disconnected and separated into a first portion CE-a disposed below the anti-deposition pattern WAL and a second portion CE-b disposed above the anti-deposition pattern WAL. The second portion CE-b may be disposed on the dam parts DM1 and DM2.

Referring to FIG. 12F, a functional layer EL may be disposed below the second electrode CE. The functional layer EL may also be disconnected by the anti-deposition pattern WAL. The functional layer EL may be disconnected and separated into a third portion EL-a disposed below the anti-deposition pattern WAL and a fourth portion EL-b disposed above the anti-deposition pattern WAL. In the display area AA (see FIG. 6), the functional layer EL and the second electrode CE may be disposed on the first electrode AE to form the light emitting element LD.

In FIG. 12F, the first portion CE-a of the second electrode is illustrated as being spaced apart from the bottom surface BS_WA of the anti-deposition pattern, but the embodiment is not limited to that configuration. In an embodiment, in the case where the first portion CE-a is formed to be separated from the second portion CE-b by exposing a portion of the bottom surface BS_WA of the anti-deposition pattern, an edge of the first portion CE-a may be formed adjacent to the bottom surface BS_WA of the anti-deposition pattern. In FIG. 12F, an edge of the second portion CE-b of the second electrode is illustrated as overlapping the edge of the protrusion pattern MTP, but the embodiment is not limited to that arrangement. In an embodiment, in the case where the second portion CE-b is formed separately from the first portion CE-a by exposing a portion of the bottom surface BS_WA of the anti-deposition pattern, the second portion CE-b may be formed to cover the edge of the protrusion pattern MTP.

FIG. 12G is a schematic view illustrating the process of forming the first encapsulation layer IL1 on the second electrode CE. In the method for manufacturing the display device according to an embodiment, a process of forming the encapsulation layer on the counter electrode may be performed after the process (S160) of forming the counter electrode, which is disconnected by the anti-deposition pattern. The first encapsulation layer IL1 may be applied to cover the second electrode CE. The first encapsulation layer IL1 may cover the bottom surface BS_WA of the anti-deposition pattern WAL, which is exposed in the grooves GV1 and GV2 due to the absence of the second electrode CE. The first encapsulation layer IL1 may be directly disposed on a bottom surface BS_WA of the anti-deposition pattern WAL. By covering the disconnected second electrode CE and the anti-deposition pattern WAL, the first encapsulation layer IL1 seals and protects the second electrode CE, other insulating layers, and conductive patterns from moisture and gas.

FIG. 12H illustrates an example of a process of forming a second encapsulation layer OL and a third encapsulation layer IL2. The second encapsulation layer OL may be applied over the first encapsulation layer IL1, and the third encapsulation layer IL2 may be disposed on the second encapsulation layer OL. In the hole area HA, the second encapsulation layer OL may be provided to fill the grooves GV1 and GV2 disposed between at least some of the dam parts DM1 and DM2. In a portion of the hole area HA where the second encapsulation layer OL is not applied, the third encapsulation layer IL2 may be directly disposed on the first encapsulation layer IL1.

Although not shown, a process of forming an input sensor ISL may be performed after forming the encapsulation layer ECL. After the display module has been fully laminated, a process for forming the module hole HH (see FIG. 4) may be performed. The module hole HH (see FIG. 4) may be formed in the hole area HA by machining through the components of the display module.

Even when the module hole HH (see FIG. 4) is formed and one surface of the display module is exposed, the display device according to an embodiment may include the second electrode that is disconnected by the anti-deposition pattern. This helps prevent moisture or gas, introduced through the module hole or the lower layers or generated in the lower layers, from being transferred to the display area via the second electrode, thereby enhancing the excellent reliability of the display device.

The display device according to an embodiment may include the anti-deposition pattern disposed below the protrusion pattern that protrudes into the groove. This allows a portion of the electrode to be disconnected by the anti-deposition pattern, thereby preventing the electrode from becoming a passage for moisture or similar substances. The display device according to an embodiment may readily form the electrode containing high content of Ag using the sputtering method. Thus, the display device according to an embodiment may include an electrode containing high content Ag, resulting in high luminous efficiency, reduced touch noise characteristics, and excellent reliability characteristics.

The method for manufacturing the display device according to an embodiment may include the process of forming the anti-deposition pattern containing fluorine or an aromatic hydrocarbon compound containing a fluorine substituent on the lower side of the protrusion pattern. As a result, even in the case where the electrode is later provided by the sputtering method, it may be formed in a disconnected configuration by the anti-deposition pattern. In the method for manufacturing the display device according to an embodiment, a portion of the electrode may be formed to be disconnected rather than to be continuous, which prevents the movement of moisture or gas through the electrode, thereby enabling the display device to have excellent reliability.

The display device according to the embodiment of the disclosure may include an anti-deposition pattern disposed below the protrusion pattern that defines the pattern hole. This configuration prevents the electrode from being continuously formed in the hole area, thereby exhibiting the excellent reliability characteristics of the device.

The display device according to an embodiment of the disclosure may include a counter electrode including high content of Ag. The counter electrode may have a disconnected structure in at least a portion of the hole area, resulting in excellent luminous efficiency and improved electrical characteristics, further enhancing the device's reliability.

The method for manufacturing the display device according to an embodiment of the disclosure may include a process of forming the anti-deposition pattern made from an aromatic hydrocarbon compound containing a fluorine-based substituent. This prevents the electrode from being formed at the portion of the anti-deposition pattern, thereby ensuring the electrode does not serve as a moisture permeable path. As a result, the method provides a display device having excellent reliability.

The above description is an example of technical features of the disclosure, and those skilled in the art to which the disclosure pertains will be able to make various modifications and variations. Thus, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising:
an electronic module; and
a display module comprising a hole area overlapping the electronic module, the display module comprising:
a base layer with a module hole corresponding to the hole area;
a light emitting element comprising a pixel electrode disposed on the base layer, a counter electrode facing the pixel electrode, and a functional layer disposed between the pixel electrode and the counter electrode;
a protrusion pattern disposed between the base layer and the pixel electrode, forming a pattern hole spaced apart from the module hole and surrounding the module hole;
a first insulating layer disposed between the base layer and the protrusion pattern, with a first opening overlapping the pattern hole;
a second insulating layer disposed between the protrusion pattern and the pixel electrode, with a second opening overlapping the pattern hole; and
an anti-deposition pattern directly disposed on a bottom surface of the protrusion pattern, wherein
the counter electrode is disconnected by the anti-deposition pattern and comprises a first portion disposed in the first opening and a second portion disposed in the second opening.

2. The display device of claim 1, wherein a bottom surface of the anti-deposition pattern is not covered by the counter electrode in the first opening.

3. The display device of claim 1, wherein the anti-deposition pattern comprises:
a core part comprising at least one substituted or unsubstituted aromatic ring; and
an aromatic hydrocarbon compound bonded to the core part, comprising at least one of a fluorine atom and a fluorine substituent.

4. The display device of claim 3, wherein
the core part has a molecular weight of less than or equal to about 300 Da and contains 1 to 5 substituted or unsubstituted aryl rings or substituted or unsubstituted heteroaryl rings, and
the fluorine substituent is represented by *—(CF₂)ₙ—CF₃, where n is an integer of greater than or equal to 1 and less than or equal to 9.

5. The display device of claim 4, wherein the aromatic hydrocarbon compound has a molecular weight of greater than or equal to about 500 Da and less than or equal to about 2,000 Da.

6. The display device of claim 1, wherein the counter electrode comprises an alloy material containing greater than or equal to about 98 vol % of Ag and is free of Mg.

7. The display device of claim 1, wherein the pixel electrode is a reflective electrode, and the counter electrode is either a transmissive electrode or a transflective electrode.

8. The display device of claim 1, wherein
the protrusion pattern does not overlap the first insulating layer and the second insulating layer and comprises a protruding tip part, and
the anti-deposition pattern overlaps a tip part of the protrusion pattern.

9. The display device of claim 1, wherein the anti-deposition pattern entirely overlaps the protrusion pattern.

10. The display device of claim 1, wherein
the display module further comprises an encapsulation layer disposed on the counter electrode,
the encapsulation layer comprises an encapsulation inorganic layer directly disposed on the counter electrode and the anti-deposition pattern.

11. The display device of claim 1, wherein, in a cross-section, a width of the first opening in a direction and a width of the second opening in the direction are each greater than a width of the pattern hole in the direction.

12. A display device comprising:
an electronic module; and
a display module comprising a hole area overlapping the electronic module and a display area distinct from the hole area, wherein,
in the hole area, the display module comprises:
a base layer in which a module hole is defined;
a circuit layer disposed on the base layer and comprising a plurality of dam parts that surround the module hole and a groove defined between the dam parts;
a display element layer disposed on the circuit layer and comprising an electrode containing Ag; and
an encapsulation layer disposed on the display element layer, wherein
the groove comprises a pattern hole defined by a protrusion pattern comprising a tip part protruding inward and an anti-deposition pattern directly disposed below the protrusion pattern; a lower opening defined below the pattern hole, overlapping the pattern hole; and an upper opening overlapping the lower opening in a thickness direction, and
the electrode is disposed on the dam parts and the groove and exposes a bottom surface of the anti-deposition pattern.

13. The display device of claim 12, wherein
the anti-deposition pattern comprises:
a core part comprising at least one substituted or unsubstituted aromatic ring; and
an aromatic hydrocarbon compound bonded to the core part, comprising at least one of a fluorine atom and a fluorine substituent,
the core part has a molecular weight of less than or equal to about 300 Da and contains 1 to 5 substituted or unsubstituted aryl rings or substituted or unsubstituted heteroaryl rings, and
the fluorine substituent is represented by *—(CF₂)ₙ—CF₃, where n is an integer of greater than or equal to 1 and less than or equal to 9.

14. The display device of claim 12, wherein
the groove is provided in plurality, and
the encapsulation layer comprises:
a first encapsulation layer that covers the plurality of grooves;
a second encapsulation layer disposed on the first encapsulation layer, overlapping some of the plurality of grooves and not overlapping other grooves; and
a third encapsulation layer disposed on the second encapsulation layer to cover the plurality of grooves.

15. The display device of claim 14, wherein the first encapsulation layer is directly disposed on a bottom surface of the anti-deposition pattern, covering the dam parts and the grooves.

16. The display device of claim 12, wherein
each of the dam parts comprises a first dam layer that defines the lower opening and a second dam layer that defines the upper opening and is disposed on the first dam layer, and
the protrusion pattern is disposed between the first dam layer and the second dam layer.

17. A method for manufacturing a display device, the method comprising:
providing a target substrate that comprises a base layer and a preliminary first insulating layer disposed on the base layer;
forming an anti-deposition pattern on the target substrate using an aromatic hydrocarbon compound containing at least one of a fluorine atom and a fluorine substituent;
forming a protrusion pattern by overlapping the anti-deposition pattern;
providing a preliminary second insulating layer on the protrusion pattern;
patterning the preliminary first insulating layer and the preliminary second insulating layer to form a first insulating layer, in which a first opening is defined, and a second insulating layer, in which a second opening is defined, and
forming a counter electrode that is disposed in the first opening and the second opening and is disconnected by the anti-deposition pattern.

18. The method of claim 17, wherein, in the forming of the counter electrode, the counter electrode is not disposed on a bottom surface of the protrusion pattern exposed to the first opening.

19. The method of claim 17, wherein the forming of the counter electrode comprises providing an alloy containing greater than or equal to about 98 vol % of Ag using a sputtering method.

20. The method of claim 17, wherein the forming of the anti-deposition pattern comprises applying the aromatic hydrocarbon compound on the target substrate using a vacuum thermal evaporation method.
